(19) United States
(12) Patent Application Publication
(10) Pub. No.: US 2024/0354458 A1
(43) Pub. Date: Oct. 24, 2024

(54) SYSTEM, METHOD AND COMPUTER PROGRAM PRODUCT FOR STRUCTURAL FLOOR CONSTRUCTION USING OPTIMIZED DESIGN

(71) Applicant: Wall to Wall, LLC, Hayward, CA (US)

(72) Inventors: Noam RONEN, Be'er Tuvia (IL); Noam BURG, Tel Aviv (IL); Ira Seth KUGELMAN, Kiryat Ono (IL); Daniel KEDEM, Tel Aviv-Jaffa (IL); Itamar PARIENTY, Matan (IL); Yaniv COHEN, Givat Ela (IL)

(73) Assignee: Wall to Wall, LLC, Hayward, CA (US)

(21) Appl. No.: 18/688,340

(22) PCT Filed: Aug. 29, 2022
(86) PCT No.: PCT/IL2022/050940

§ 371 Date: Feb. 29, 2024

Related U.S. Application Data
(60) Provisional application No. 63/239,141, filed on Aug. 31, 2021.

(51) Int. Cl. G06F 30/13; E04B 5/10; E04B 5/12; E04B 5/14

(52) U.S. Cl. CPC G06F 30/13; E04B 5/10; E04B 5/12; E04B 5/14

(57) ABSTRACT

A system for designing structural floors, the system comprising a hardware processor configured to perform an iteration including determining whether an individual rectangle, defined within a building area, can or cannot, when covered by whole floor cassettes, be safely carried by either the vertical structural supporting elements beneath that rectangle or by the horizontal structural supporting elements beneath said individual rectangle.

### CROSS-REFERENCE TO RELATED APPLICATIONS

This application is a national stage application under 35 USC 371 of International Application No. PCT/IL2022/050940, filed Aug. 29, 2022, which claims the benefit of U.S. Provisional Application No. 63/239,141, filed Aug. 31, 2021. The entire contents of each priority application is hereby incorporated herein by reference.

### FIELD OF THE DISCLOSURE

The present invention relates generally to construction, and more particularly to construction of floors.

### BACKGROUND OF THE DISCLOSURE

State-of-the-art CAD/CAM software divides the design interface according to disciplines e.g., including the following three disciplines:
Architectural
Structural
Systems and MEP

The structural CAM interface allows structural engineers to do work that involves planning safe buildings, capable of withstanding loads and ensuring building integrity, usually according to predetermined local building codes.

Floor cassettes are known in the art and are available e.g. here: https://pasquill.co.uk/fkiir-sultions/floor-cassettes/ and here: https://www.donaldsontimberenginnering.co.uk/products/panels/floor-cassettes/ and here: https://pyrda.com/au/wp-content/uploads/Pyrda-Floor-Cassette-Manual.pdf and https://www.thomasarmstrongtimber.co.uk/engineered-timber-products/floor-cassettes and https://fast-house/co.uk/products/floor-cassette/. Each cassette may be a structural e.g., load-bearing element for floor construction, factory made e.g., from steel or timber, and may, for example, include floor joists joined with trimmers or end-joists and/or trusses and/or strongbacks typically perpendicular to the trusses and/or floor sheathing. Sheathing may comprise particleboard flooring and/or wet area flooring materials, such as fiber cement board. Cassettes may include acoustic and/or fire protection components. To install, cassettes may for example be lifted into place and may be braced to a supporting structure.

The disclosures of all publications and patent documents mentioned in the specification, and of the publications and patent documents cited therein directly or indirectly, are hereby incorporated by reference other than subject matter disclaimers or disavowals. If the incorporated material is inconsistent with the express disclosure herein, the interpretation is that the express disclosure herein describes certain embodiments, whereas the incorporated material describes other embodiments. Definition/s within the incorporated material may be regarded as one possible definition for the term/s in question.

### SUMMARY OF THE DISCLOSURE

Certain embodiments of the present invention seek to provide circuitry typically comprising at least one processor in communication with at least one memory, with instructions stored in such memory executed by the processor to provide functionalities which are described herein in detail. Any functionality described herein may be firmware-implemented or processor-implemented, as appropriate.

Certain embodiments seek to provide a system and method which determines floor cassette size systematically and/or safely and/or economically, where floor cassettes typically comprise structure elements and typically may be supplied in almost any dimensions. However, despite this, minimalization of the number of different cassette dimensions required is typically still desirable for simplicity (e.g. so as to adjust cassette manufacturing machinery settings as few times as possible) and/or minimalization of the number of cassettes e.g. by maximalization of their dimensions is desirable because this reduces assembly costs by reducing the number of workpieces that need to be assembled into a whole. Also, very small cassettes may be too small to support constructional requirements.

According to certain embodiments, floor cassette size is determined separately for each pair of parallel structural elements on the floor below, which is capable of supporting floor cassettes between them.

According to certain embodiments, floor cassette size for cassettes deployed between a given pair of parallel structural elements on the floor below, is uniform, so as to reduce the number of different cassette dimensions required for a given building project.

At least one method herein proceeds over rectangles defined within a building area, in a given order, and performs the following iteration, on each individual rectangle from among the rectangles which is not covered with cassettes: determining. e.g. by applying system rules, whether the individual rectangle, if covered by whole cassettes, can be safely carried by either the vertical structural walls beneath that rectangle, or by the horizontal structural walls beneath that rectangle: if so, cover the individual rectangle with whole cassettes, and, otherwise, delete cassettes covering at least one rectangle which precede/s the individual rectangle. The method may then continue until all rectangles defined within the building area are covered with cassettes e.g., until each rectangle defined within the building area is covered with whole cassettes.

It is appreciated that any reference herein to, or recitation of, an operation being performed, e.g. if the operation is performed at least partly in software, is intended to include both an embodiment where the operation is performed in its entirety by a server A, and also to include any type of “outsourcing” or “cloud” embodiments in which the operation, or portions thereof, is or are performed by a remote processor P (or several such), which may be deployed off-shore or “on a cloud”, and an output of the operation is then communicated to, e.g. over a suitable computer network, and used by, server A. Analogously, the remote processor P may not, itself, perform all of the operations, and, instead, the remote processor P itself may receive output/s of portion/s of the operation from yet another processor/s P′, may be deployed off-shore relative to P, or “on a cloud”, and so forth.

The present invention typically includes at least the following embodiments:

Embodiment 1. A system for designing structural floors, the system comprising a hardware processor configured to perform an iteration including determining whether an individual rectangle, defined within a building area, can or cannot, when covered by whole floor cassettes, be safely carried by either the vertical structural supporting elements beneath that rectangle or by the horizontal structural supporting elements beneath the individual rectangle, the determining including: digitally covering the individual rectangle with whole digital cassettes, for at least one individual rectangle which, when covered by whole cassettes, can be safely carried by either the vertical structural supporting elements beneath that rectangle or by the horizontal structural supporting elements beneath that individual rectangle; and/or digitally deleting cassettes which digitally cover at least one rectangle which precede/s the individual rectangle, for at least one individual rectangle which, when covered by whole cassettes, cannot be safely carried by the vertical structural supporting elements beneath that rectangle and cannot be safely carried by the horizontal structural supporting elements beneath that individual rectangle. Typically, the hardware processor is used to repeat the iteration for each individual rectangle, from among all rectangles defined within the building area, which is not digitally covered with cassettes, thereby to design a structural floor.

Typically, floor cassettes, being a structural element, cannot be cut or sliced and whole floor cassettes, rather than cut portions of floor cassettes, must be used, to maintain safe construction. However, floor cassettes can be custom-made to size, for a wide variety of sizes. According to certain embodiments, rather than manufacturing cassettes and using an a priori inventory of sizes for designing and subsequent construction of buildings, buildings are designed, and for each floor level whose structural elements have been designed, a subsequent floor slab for the next higher floor level is designed, including finding a floor cassette size S which enables portions of the floor slab lying between parallel (portions of) structural elements to be entirely tiled with whole cassettes, and subsequently, cassettes of size S, specifically, are manufactured and, subsequently, are physically put into place and, typically, secured. Typically, each cassette must always be placed above 2 supporting elements which are typically on opposite sides of the cassette, typically along the entire lengths of both of these opposite sides.

Embodiment 2. The system of any of the preceding embodiments wherein the deleting includes deleting cassettes covering but one rectangle which precedes the individual rectangle, and deleting another rectangle which precedes the individual rectangle only during a subsequent iteration for at least one rectangle R which, after the but one rectangle is deleted, is not covered with cassettes, and only if the rectangle R when covered by whole cassettes, cannot be safely carried by the vertical structural supporting elements beneath rectangle R and cannot be safely carried by the horizontal structural supporting elements beneath rectangle R.

Embodiment 3. The system of any of the preceding embodiments wherein the iterations are repeated, proceeding over rectangles defined not covered with cassettes within a building area, in a predetermined order.

Embodiment 4. The system of any of the preceding embodiments wherein system rules which take in account known structural characteristics of physical cassettes, are stored in memory and are applied to determine whether an individual rectangle, defined within a building area, can or cannot, when covered by whole physical cassettes corresponding in size to the digital cassettes, be safely carried by either the vertical structural supporting elements beneath that rectangle, or by the horizontal structural supporting elements beneath the individual rectangle.

Embodiment 5. A method for designing structural floors, the method comprising:
using a hardware processor to perform an iteration including determining whether an individual rectangle, defined within a building area, can or cannot, when covered by whole cassettes, be safely carried by either the vertical structural supporting elements beneath that rectangle, or by the horizontal structural supporting elements beneath the individual rectangle, including digitally covering the individual rectangle with whole digital cassettes, if the individual rectangle, when covered by whole physical cassettes corresponding in size to the digital cassettes, can be safely carried by either the vertical structural supporting elements beneath that rectangle, or by the horizontal structural supporting elements beneath that individual rectangle; and digitally deleting digital cassettes which digitally cover at least one rectangle which precede/s the individual rectangle, if the individual rectangle, when covered by whole physical cassettes, corresponding in size to the digital cassettes, cannot be safely carried by the vertical structural supporting elements beneath that rectangle, and cannot be safely carried by the horizontal structural supporting elements beneath that individual rectangle; and using the hardware processor to repeat the iteration for each individual rectangle, from among all rectangles defined within the building area, which is not digitally covered with digital cassettes, thereby to design a structural floor.

Embodiment 6. The method of any of the preceding embodiments and also comprising providing N physical cassettes of a given size, once all rectangles defined within the building area have been digitally covered, by the hardware processor, with N whole cassettes of the given size.

Embodiment 7. The method of any of the preceding embodiments and also comprising building the structural floor by physically covering each of the rectangles with physical cassettes, wherein the physical cassettes correspond in size to the digital cassettes.

Embodiment 8. The system of any of the preceding embodiments wherein each time a current iteration is performed subsequent to cassettes having been deleted in a previous iteration, whole digital cassettes used to digitally cover at least one rectangle during the current iteration, are smaller than the cassettes deleted during the previous iteration.

Embodiment 9. The system of any of the preceding embodiments wherein all digital cassettes used for digitally covering are longer than a minimum allowed cassette length stored in the system.

Embodiment 10. The method of any of the preceding embodiments wherein system rules which take in account known structural characteristics of physical cassettes, are stored in memory and are applied to determine whether an individual rectangle, defined within a building area, can or cannot, when covered by whole physical cassettes corresponding in size to the digital cassettes, be safely carried by either the vertical structural supporting elements beneath that rectangle or by the horizontal structural supporting elements beneath the individual rectangle.

Embodiment 11. The method of any of the preceding embodiments and wherein the physical cassettes used to physically cover rectangles when building the structural floor, have the known structural characteristics.

Embodiment 12. A computer program product, comprising a non-transitory tangible computer readable medium having computer readable program code embodied therein, the computer readable program code adapted to be executed to implement a method for designing structural floors, the method comprising: using a hardware processor to perform an iteration including: determining whether an individual rectangle, defined within a building area, can or cannot, when covered by whole cassettes, be safely carried by either the vertical structural supporting elements beneath that rectangle or by the horizontal structural supporting elements beneath the individual rectangle, including: digitally covering the individual rectangle with whole digital cassettes, if the individual rectangle, when covered by whole physical cassettes corresponding in size to the digital cassettes, can be safely carried by either the vertical structural supporting elements beneath that rectangle or by the horizontal structural supporting elements beneath that individual rectangle; and digitally deleting digital cassettes which digitally cover at least one rectangle which precede/s the individual rectangle, if the individual rectangle, when covered by whole physical cassettes, corresponding in size to the digital cassettes, cannot be safely carried by the vertical structural supporting elements beneath that rectangle and cannot be safely carried by the horizontal structural supporting elements beneath that individual rectangle; and using the hardware processor to repeat the iteration for each individual rectangle, from among all rectangles defined within the building area, which is not digitally covered with digital cassettes, thereby to design a structural floor.

Embodiment 13. A system according to any of the preceding embodiments wherein the hardware processor repeats the iteration until the rectangle is digitally covered with cassettes which can be safely carried by either the vertical structural walls beneath that rectangle, or by the horizontal structural walls beneath the individual rectangle.

More generally, trial and error may be used for determining cassette size or any other operation herein e.g., trial until fail or until mission complete. Typically, responsive to failure to tile using a given cassette size, the method digitally deletes cassettes if an individual rectangle, when covered by whole cassettes, cannot be safely carried.

Embodiment 14. A system according to any of the preceding embodiments wherein the structural supporting elements comprise structural supporting walls, beams, or ledgers.

Embodiment 15. The system of any of the preceding embodiments wherein when at least one iteration fails for a first size of cassettes, because the rectangle cannot be safely carried by at least one of the vertical structural supporting elements beneath that rectangle or the horizontal structural supporting elements beneath that rectangle, and wherein another iteration is then performed for a second size of cassettes.

Embodiment 16. The system of any of the preceding embodiments wherein one dimension, D1, of the second size of cassettes, is smaller than dimension D1 of the first size of cassettes.

Embodiment 17. The system of any of the preceding embodiments wherein the another iteration comprises a sequence of plural iterations, performed using a respective sequence of cassettes having a respective sequence of cassette sizes having one dimension, D1, whose size is s2, s3, s4 respectively, and wherein s4 is smaller than s3 which is smaller than s2, thereby to prefer a flooring plan which uses larger cassettes over a flooring plan which uses smaller cassettes.

Embodiment 18. The system of any of the preceding embodiments wherein a dimension D2 of the cassettes is equal to a distance between supporting elements beneath that cassette.

Embodiment 19. The system of any of the preceding embodiments wherein the cassettes in the sequence of cassettes all have a dimension D2 equal to a distance between supporting elements beneath cassettes.

Embodiment 20. A system according to any of the preceding embodiments wherein the determining comprises, for at least one floor F, retrieving all structural elements from a digital plan of a floor below floor F including each element's type (interior space, exterior space, in-wall, etc.) and coordinates, creating, therefrom, a 2D sort representation of all the structural elements; and, accordingly, generating a list of rectangles including merging plural adjacent rectangles of a single type into a single rectangle.

Embodiment 21. A system according to any of the preceding embodiments wherein a floor area corresponding to the single rectangle is physically populated by floor cassettes and at least two parallel sides of the single rectangle are physically supported by structural elements in a floor slab below.

Embodiment 22. A system according to any of the preceding embodiments wherein the digitally covering the individual rectangle with whole digital cassettes comprises identifying, in a grid of lines, logical rectangles which enclose interior spaces, defining the logical rectangles as fields and digitally covering the fields with whole digital cassettes.

Embodiment 23. A system according to any of the preceding embodiments wherein the defining the logical rectangles as fields comprises unifying plural logical rectangles, found to cover portions of an interior space whose location and dimensions are known from a building design file, into a single larger logical rectangle covering the interior space which includes all of the portions.

Also provided, excluding signals, is a computer program comprising computer program code means for performing any of the methods shown and described herein, when the program is run on at least one computer; and a computer program product, comprising a typically non-transitory computer-usable or -readable medium e.g. non-transitory computer-usable or -readable storage medium, typically tangible, having a computer readable program code embodied therein, the computer readable program code adapted to be executed to implement any or all of the methods shown and described herein. The operations in accordance with the teachings herein may be performed by at least one computer specially constructed for the desired purposes, or by a general-purpose computer specially configured for the desired purpose by at least one computer program stored in a typically non-transitory computer readable storage medium. The term “non-transitory” is used herein to exclude transitory, propagating signals or waves, but to otherwise include any volatile or non-volatile computer memory technology suitable to the application.

Any suitable processor/s, display and input means may be used to process, display e.g. on a computer screen or other computer output device, store, and accept information such as information used by or generated by any of the methods and apparatus shown and described herein: the above processor/s, display and input means including computer programs, in accordance with all or any subset of the embodiments of the present invention. Any or all functionalities of the invention shown and described herein, such as but not limited to operations within flowcharts, may be performed by any one or more of at least one conventional personal computer processor, workstation or other programmable device or computer or electronic computing device or processor, either general-purpose or specifically constructed, used for processing: a computer display screen and/or printer and/or speaker for displaying: machine-readable memory such as flash drives, optical disks, CDROMs, DVDs, BluRays, magnetic-optical discs or other discs: RAMs, ROMs, EPROMS, EEPROMs, magnetic or optical or other cards, for storing, and keyboard or mouse for accepting. Modules illustrated and described herein may include any one or combination or plurality of a server, a data processor, a memory/computer storage, a communication interface (wireless (e.g., BLE) or wired (e.g., USB)), or a computer program stored in memory/computer storage.

The term “process” as used above is intended to include any type of computation or manipulation, or transformation of data represented as physical, e.g., electronic, phenomena which may occur or reside e.g., within registers and/or memories of at least one computer or processor. Use of nouns in singular form is not intended to be limiting; thus, the term processor is intended to include a plurality of processing units which may be distributed or remote, the term server is intended to include plural typically interconnected modules running on plural respective servers, and so forth.

The above devices may communicate via any conventional wired or wireless digital communication means, e.g., via a wired or cellular telephone network or a computer network such as the Internet.

The apparatus of the present invention may include, according to certain embodiments of the invention, machine readable memory containing or otherwise storing a program of instructions which, when executed by the machine, implements all or any subset of the apparatus, methods, features and functionalities of the invention shown and described herein. Alternatively, or in addition, the apparatus of the present invention may include, according to certain embodiments of the invention, a program as above which may be written in any conventional programming language, and optionally a machine for executing the program, such as but not limited to, a general purpose computer which may optionally be configured or activated in accordance with the teachings of the present invention. Any of the teachings incorporated herein may, wherever suitable, operate on signals representative of physical objects or substances.

The embodiments referred to above, and other embodiments, are described in detail in the next section.

Any trademark occurring in the text or drawings is the property of its owner and occurs herein merely to explain or illustrate one example of how an embodiment of the invention may be implemented.

Unless stated otherwise, terms such as, “processing”, “computing”, “estimating”, “selecting”, “ranking”, “grading”, “calculating”, “determining”, “generating”, “reassessing”, “classifying”, “generating”, “producing”, “stereo-matching”, “registering”, “detecting”, “associating”, “superimposing”, “obtaining”, “providing”, “accessing”, “setting” or the like, refer to the action and/or processes of at least one computer/s or computing system/s, or processor/s or similar electronic computing device/s or circuitry, that manipulate and/or transform data which may be represented as physical, such as electronic, quantities e.g. within the computing system's registers and/or memories, and/or may be provided on-the-fly, into other data which may be similarly represented as physical quantities within the computing system's memories, registers or other such information storage, transmission or display devices or may be provided to external factors e.g. via a suitable data network. The term “computer” should be broadly construed to cover any kind of electronic device with data processing capabilities, including, by way of non-limiting example, personal computers, servers, embedded cores, computing systems, communication devices, processors (e.g. digital signal processor (DSP), microcontrollers, field programmable gate array (FPGA), application specific integrated circuit (ASIC), etc.) and other electronic computing devices. Any reference to a computer, controller or processor is intended to include one or more hardware devices e.g., chips, which may be co-located or remote from one another. Any controller or processor may, for example, comprise at least one CPU, DSP, FPGA or ASIC, suitably configured in accordance with the logic and functionalities described herein.

Any feature or logic or functionality described herein may be implemented by processor/s or controller/s configured as per the described feature or logic or functionality, even if the processor/s or controller/s are not specifically illustrated for simplicity. The controller or processor may be implemented in hardware, e.g., using one or more Application-Specific Integrated Circuits (ASICs) or Field-Programmable Gate Arrays (FPGAs), or may comprise a microprocessor that runs suitable software, or a combination of hardware and software elements.

The present invention may be described, merely for clarity, in terms of terminology specific to, or references to, particular programming languages, operating systems, browsers, system versions, individual products, protocols and the like. It will be appreciated that this terminology or such reference/s is intended to convey general principles of operation clearly and briefly, by way of example, and is not intended to limit the scope of the invention solely to a particular programming language, operating system, browser, system version, or individual product or protocol. Nonetheless, the disclosure of the standard or other professional literature defining the programming language, operating system, browser, system version, or individual product or protocol in question, is incorporated by reference herein in its entirety.

Elements separately listed herein need not be distinct components and alternatively may be the same structure. A statement that an element or feature may exist is intended to include (a) embodiments in which the element or feature exists: (b) embodiments in which the element or feature does not exist; and (c) embodiments in which the element or feature exist selectably e.g., a user may configure or select whether the element or feature does or does not exist.

Any suitable input device, such as but not limited to a sensor, may be used to generate or otherwise provide information received by the apparatus and methods shown and described herein. Any suitable output device or display may be used to display or output information generated by the apparatus and methods shown and described herein. Any suitable processor/s may be employed to compute or generate or route, or otherwise manipulate or process information as described herein and/or to perform functionalities described herein and/or to implement any engine, interface or other system illustrated or described herein. Any suitable computerized data storage e.g., computer memory, may be used to store information received by or generated by the systems shown and described herein. Functionalities shown and described herein may be divided between a server computer and a plurality of client computers. These or any other computerized components shown and described herein may communicate between themselves via a suitable computer network.

The system shown and described herein may include user interface/s e.g. as described herein, which may, for example, include all or any subset of an interactive voice response interface, automated response tool, speech-to-text transcription system, automated digital or electronic interface having interactive visual components, web portal, visual interface loaded as web page/s or screen/s from server/s via communication network/s to a web browser or other application downloaded onto a user's device, automated speech-to-text conversion tool, including a front-end interface portion thereof and back-end logic interacting therewith. Thus, the term user interface, or “UI” as used herein, includes also the underlying logic which controls the data presented to the user e.g. by the system display and receives and processes and/or provides to other modules herein, data entered by a user e.g. using her or his workstation/device.

### BRIEF DESCRIPTION OF THE FIGURES

Example embodiments are illustrated in the various drawings. Specifically:

FIGS. 1A-58 are simplified diagrams of certain embodiments including FIGS. 2A-2B, 37 and 54 which are simplified flowchart illustrations of methods operative in accordance with certain embodiments: all or any subset of the illustrated operations may be provided, in any suitable order e.g., as shown; and FIGS. 55-58 which are tables. It is appreciated that FIGS. 2A-2B and 54 illustrate field creation processes, where all fields are created as a batch in FIG. 54, where fields are created “on the fly”. e.g. using a “discovery” process which finds and populates a next field, in the method of FIG. 2A-2B. Typically, when a new field has been created e.g. by operation 1150 in FIG. 2B, the field may be populated (operation 1160) using the method of FIG. 37.

Arrows between modules may be implemented as APIs and any suitable technology may be used for interconnecting functional components or modules illustrated herein in a suitable sequence or order e.g. via a suitable API/Interface. For example, state of the art tools may be employed, such as but not limited to Apache Thrift and Avro which provide remote call support. Or, a standard communication protocol may be employed, such as but not limited to HTTP or MQTT, and may be combined with a standard data format, such as but not limited to JSON or XML. According to one embodiment, one of the modules may share a secure API with another. Communication between modules may comply with any customized protocol or customized query language or may comply with any conventional query language or protocol.

Methods and systems included in the scope of the present invention may include any subset or all of the functional blocks shown in the specifically illustrated implementations by way of example, in any suitable order e.g., as shown. Flows may include all or any subset of the illustrated operations, suitably ordered e.g., as shown. Tables herein may include all or any subset of the fields and/or records and/or cells and/or rows and/or columns described.

Computational, functional or logical components described and illustrated herein, can be implemented in various forms, for example, as hardware circuits, such as but not limited to custom VLSI circuits or gate arrays or programmable hardware devices, such as but not limited to FPGAs, or as software program code stored on at least one tangible or intangible computer readable medium and executable by at least one processor, or any suitable combination thereof. A specific functional component may be formed by one particular sequence of software code, or by a plurality of such, which collectively act or behave, or act as described herein with reference to the functional component in question. For example, the component may be distributed over several code sequences, such as but not limited to objects, procedures, functions, routines and programs, and may originate from several computer files which typically operate synergistically.

Each functionality or method herein may be implemented in software (e.g. for execution on suitable processing hardware such as a microprocessor or digital signal processor), firmware, hardware (using any conventional hardware technology such as Integrated Circuit technology), or any combination thereof.

Functionality or operations stipulated as being software-implemented, may, alternatively, be wholly or fully implemented by an equivalent hardware or firmware module, and vice-versa. Firmware implementing functionality described herein, if provided, may be held in any suitable memory device and a suitable processing unit (aka processor) may be configured for executing firmware code. Alternatively, certain embodiments described herein may be implemented partly or exclusively in hardware, in which case all or any subset of the variables, parameters, and computations described herein, may be in hardware.

Any module or functionality described herein may comprise a suitably configured hardware component or circuitry. Alternatively or in addition, modules or functionality described herein may be performed by a general-purpose computer or more generally by a suitable microprocessor, configured in accordance with methods shown and described herein, or any suitable subset, in any suitable order, of the operations included in such methods, or in accordance with methods known in the art.

Any logical functionality described herein may be implemented as a real time application, if and as appropriate, and which may employ any suitable architectural option, such as but not limited to FPGA, ASIC, or DSP, or any suitable combination thereof.

Any hardware component mentioned herein may, in fact, include either one or more hardware devices, e.g., chips, which may be co-located, or remote from one another.

Any method described herein is intended to include, within the scope of the embodiments of the present invention, also any software or computer program performing all or any subset of the method's operations, including a mobile application, platform or operating system, e.g. as stored in a medium, as well as combining the computer program with a hardware device to perform all or any subset of the operations of the method.

Data can be stored on one or more tangible or intangible computer readable media stored at one or more different locations, different network nodes, or different storage devices at a single node or location.

It is appreciated that any computer data storage technology, including any type of storage or memory and any type of computer components and recording media that retain digital data used for computing for an interval of time, and any type of information retention technology, may be used to store the various data provided and employed herein. Suitable computer data storage or information retention apparatus may include any apparatus which is primary, secondary, tertiary or off-line; which is of any type or level or amount or category of volatility, differentiation, mutability, accessibility, addressability, capacity, performance and energy use; and which is based on any suitable technologies such as semiconductor, magnetic, optical, paper and others.

### DETAILED DESCRIPTION OF THE DISCLOSURE

Modern building design processes utilize different disciplines, so it becomes desirable that each professional be able to do his/her work without interfering with the other disciplines, and without needing integrated knowledge from other disciplines.

Companies that pre-fabricate buildings seek to design the buildings carefully before manufacturing. Sometimes, buildings include panels that connect to become one structure. This means that the CAM and CAD of a project can be somewhat repetitive and time consuming. Each project may have its own design considerations (e.g. lot size and/or apartment dimensions and/or local codes) which may impact the panel design choices which translate to tedious manual work, as there are multiple panels per building space (e.g., floor, apartment, roof, parking garage, etc.). Also, results depend on the human modeler, thus can change from one person to the other, having different levels of precision and details depending on the person's level of skill. This is typically a trial-and-error process which, in many cases, even if a candidate solution is found, needs to be checked against other post-design considerations (e.g., manufacturing stages).

In contrast, the automated embodiments described herein save time and effort, and provide high levels of accuracy for the design process of a panelized building, and specifically for panelized structural floors made of steel. These panels or cassettes may serve as building blocks of a structural floor for a building.

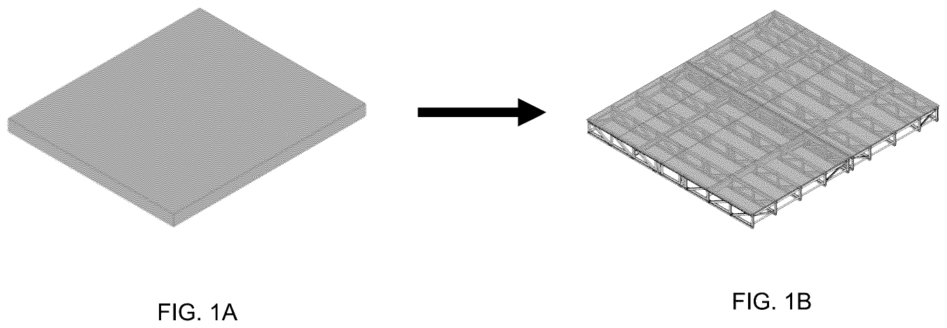

Specifically. FIG. 1 illustrates the initial and final state of a floor. Element A shows an architectural floor slab (e.g. for an entire level of a building e.g. the building's first floor or second floor, etc.) or portion thereof that may serve as input for structural modeling of a floor. Element B illustrates a possibility for the final detailed output of a structural design. Thus, element A may comprise a floor slab from an architectural CAD model with suitable dimensions, which may serve as an input to a process of adding a truss for a structural model. In the illustrated example, the floor slab or portion thereof which is illustrated includes two connected cassettes, aka panels. In the illustrated example, six inner or internal trusses are shown, plus each cassette may have additional “edge” trusses on their edges.

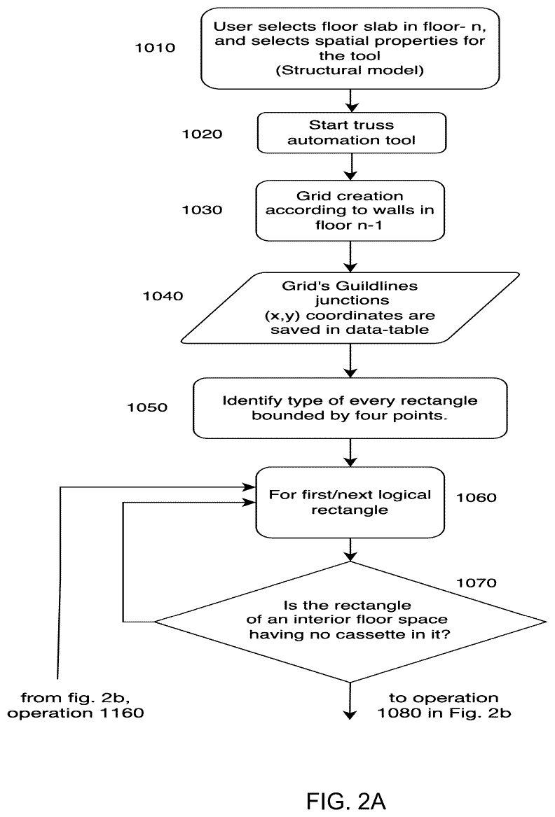

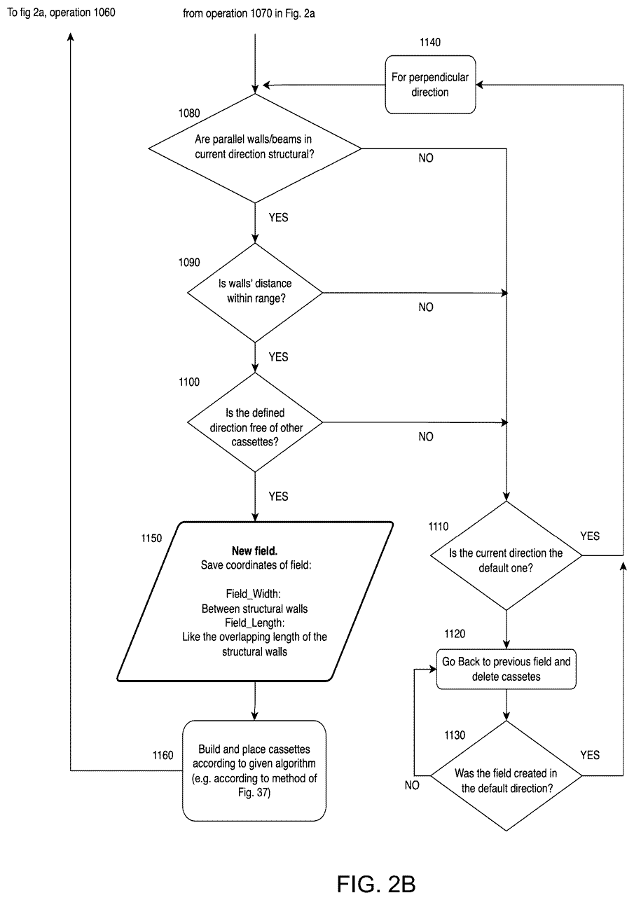

FIGS. 2A-2B, taken together, form a simplified flow-chart illustration of a method for modeling and filling a floor with cassettes. The operations of FIGS. 2A-2B may include all or any subset of the following operations, suitably ordered e.g., as follows:
Operation 1010: User selects floor slab in floor-n, and selects spatial properties for the tool (structural model)
Operation 1020: Start truss automation tool
Operation 1030: Grid creation according to walls in floor n-1.

The grid which is created is typically digital, and includes points, and for each such point, horizontal and vertical lines running through that point. Thus, the grid lines include horizontal lines which are parallel to one another but not (necessarily) equally spaced, and vertical lines which are parallel to one another, but not (necessarily) equally spaced. Each intersection of one wall edge with another wall edge, is represented, in the grid, by a point. Thus, typically, when one wall intersects another, this typically yields four points, since each of the two (main) edges of the first wall intersect each of the two (main) edges of the second wall. If a half-wall ends in the midst of an interior or exterior space, this typically yields two points, since the half-wall has two main edges.
Operation 1040: Grid's Guidelines (grid lines') junctions' (x,y) coordinates are saved in a data-table
Operation 1050: Identify type of every rectangle bounded by four points.
Operation 1060: For first/next logical rectangle
Operation 1070: Does the rectangle of an interior floor space have no cassette in it?

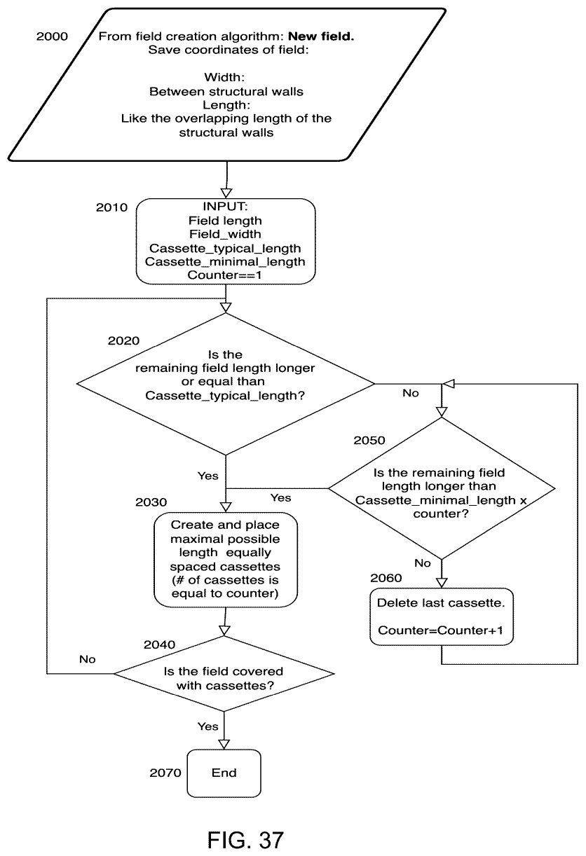

If operation 1070 in FIG. 2A is yes, go to operation 1080 in FIG. 2B
Operation 1080: Are parallel walls/beams in current direction structural?
Operation 1090: Is walls' distance within range?
Operation 1100: Is the defined direction free of other cassettes? If not, then proceed to operation 1110. If so, go to operation 1150.
Operation 1110: Is the current direction the default one? If so, then proceed to operation 1140.
Operation 1120: Go back to previous field and delete cassettes
Operation 1130: Was the field created in the default direction? If so, then proceed to operation 1140.
Operation 1140: For perpendicular direction
Operation 1150: New field (e.g., define the logical rectangle currently under consideration as a new field). Save coordinates of field:
Field_Width: Between structural walls
Field_Length: Like the overlapping length of the structural walls
Operation 1160: Build and place cassettes according to given algorithm (e.g., according to method of FIG. 37). Then, from FIG. 2B, operation 1160, return to operation 1060 in FIG. 2A.

FIG. 3 illustrates an example of floor n-1 without the next floor on top of it.

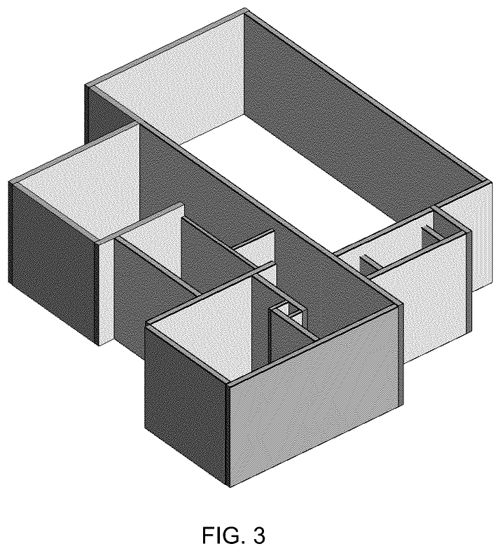

FIG. 4 illustrates an example of floor n-1 with architectural floor-n on top of it.

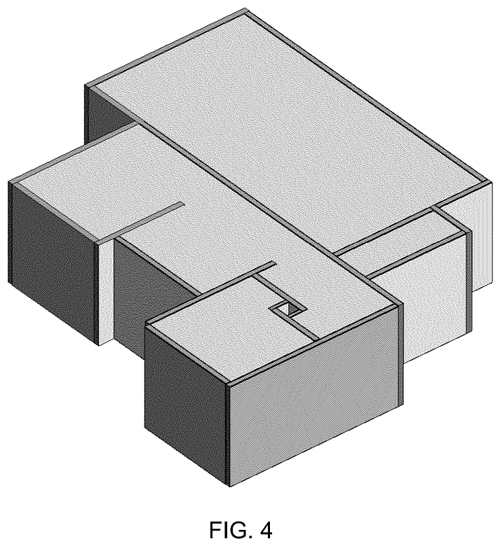

FIG. 5 illustrates an example of floor-n after the modelling of a structural cassette array.

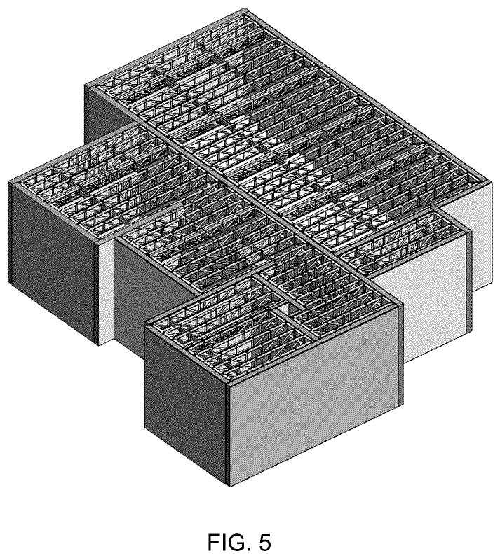

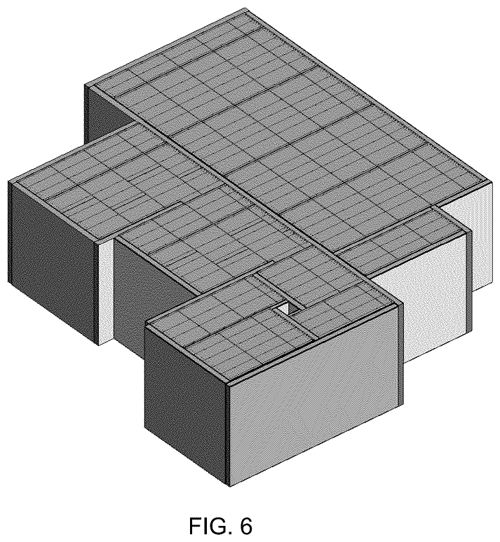

FIG. 6 illustrates an additional structural component such as sheathing which may be added.

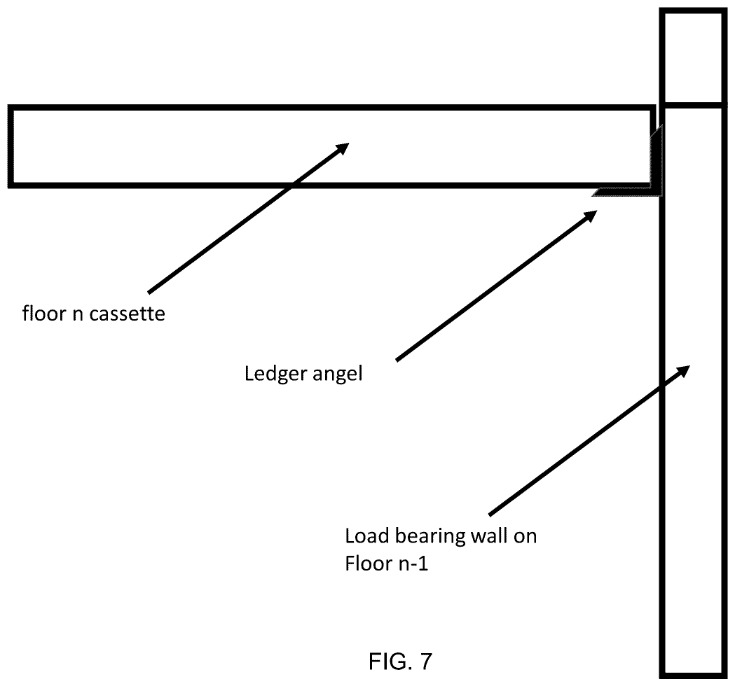

FIG. 7 illustrates modeling and designing of a structural floor which is dependent on many factors and/or rules. For instance, a floor cassette may need to be supported by a ledger angle. The ledger angle may need to be supported by a structural wall or beam.

It is appreciated that a “ledger” may, for example, comprise a horizontal support piece which may be deployed to support ends of a floor cassette or structural component of, say, a deck or porch or other weight-bearing element. A ledger may be secured to a structural element such as a wall, and may provide a bearing point for other structural members such as, say, floor cassettes. According to an embodiment, at least one cassette, or all cassettes, are supported or carried by ledgers e.g., because edges of the cassette are seated on ledger/s.

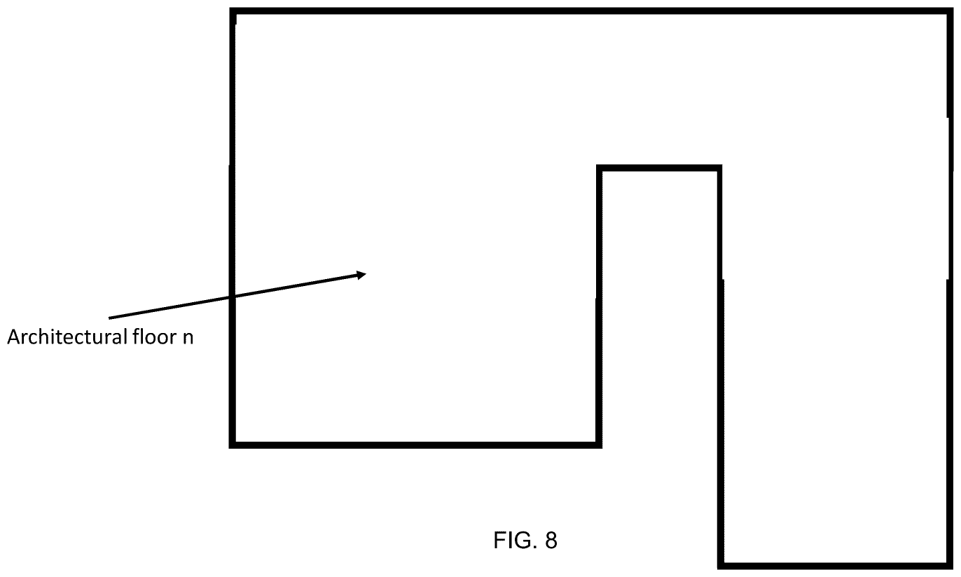

FIG. 8 illustrates a top view of an example architectural floor slab-automation tool input.

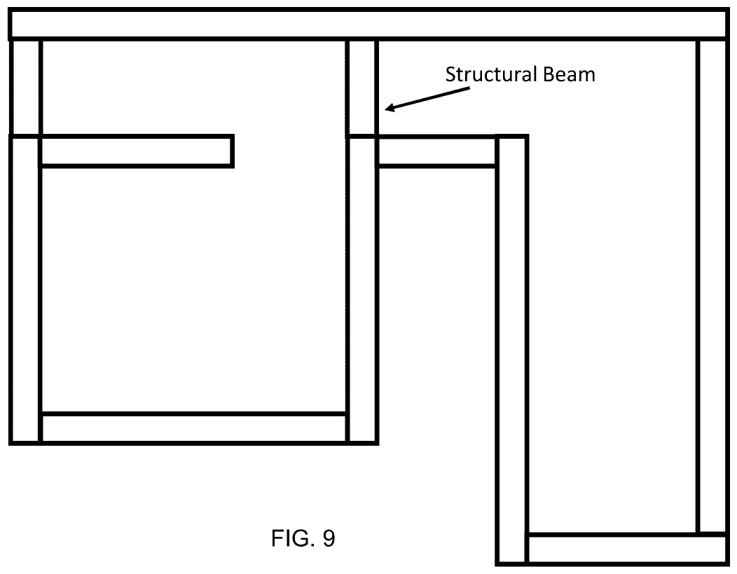

FIG. 9 illustrates walls on a floor below which are used for defining the different areas in the building.

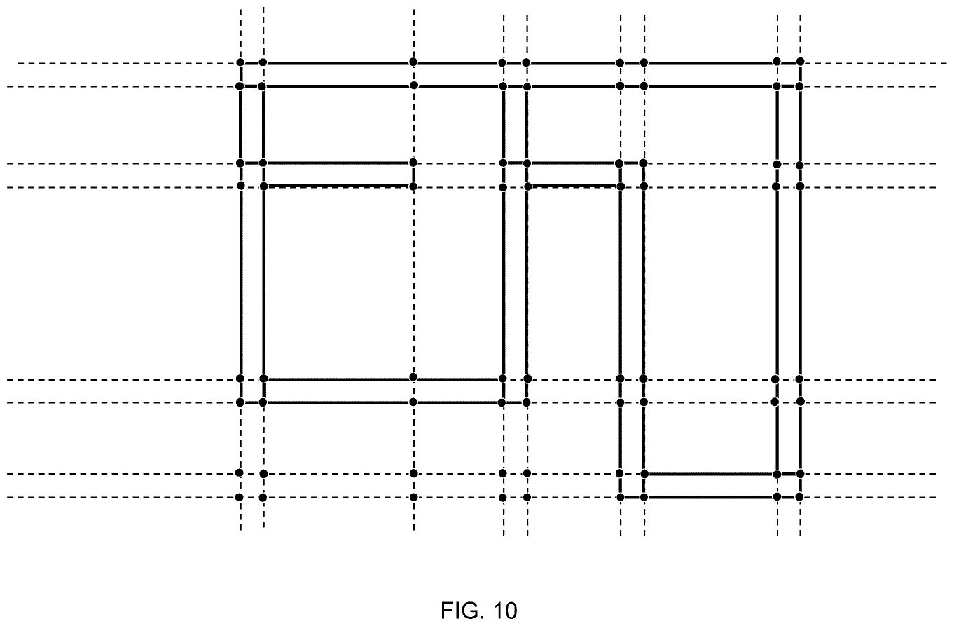

FIG. 10 illustrates a floorplan used to create a grid of lines that form rectangles. These rectangles are then used to identify the spaces relevant for modelling.

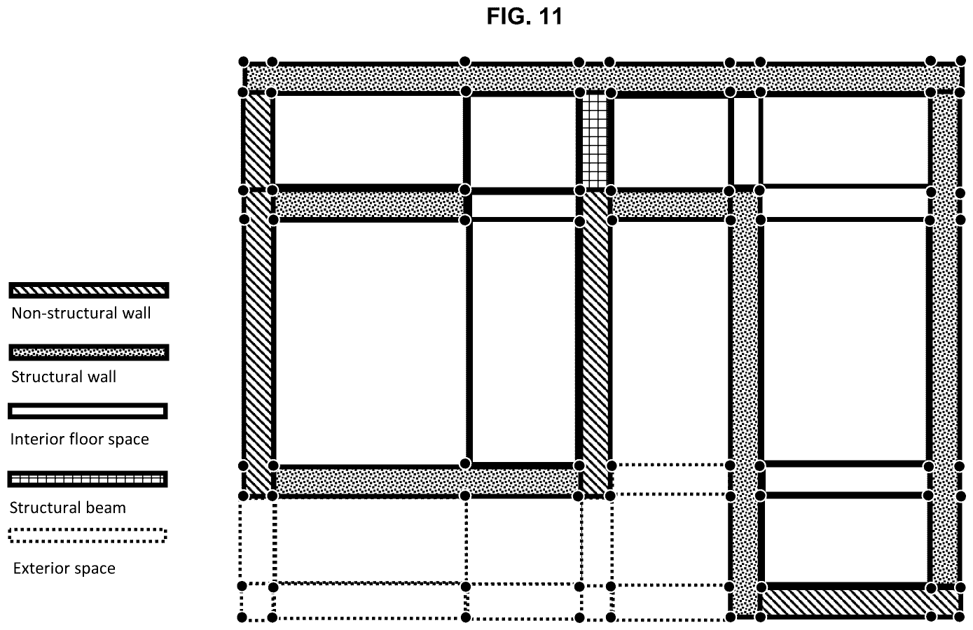

In FIG. 11, each rectangle encloses a different space, such as interior spaces and load bearing walls. These are identified and allow the tool to define fields and place cassettes. Typically, each field comprises a rectangular floor area, which is to be populated by floor cassettes, and which has opposite sides which overlie, hence are supported by, (portions of) parallel structural elements of the floor below, where the distance between these elements does not exceed the maximal allowable dimension of a floor cassette.

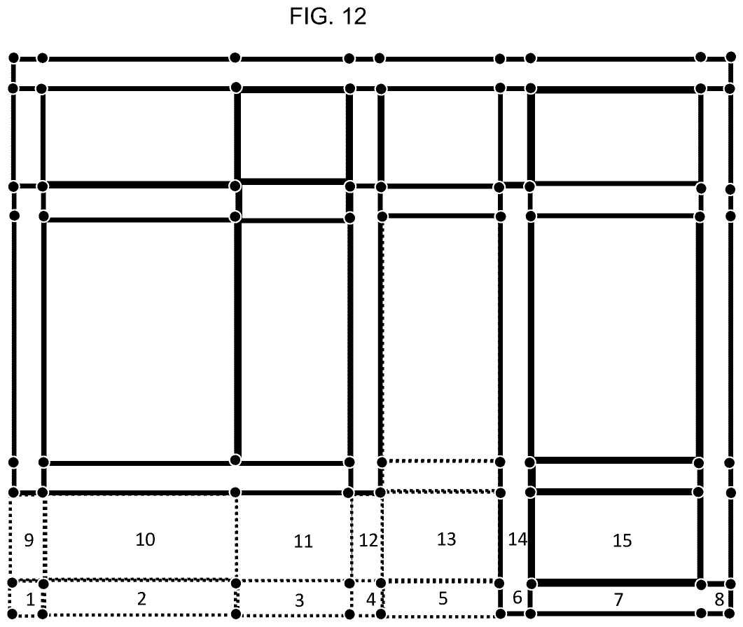

FIG. 12 illustrates grid scanning until reaching the first rectangle that represents an interior space.

FIGS. 9 to 12 are useful in understanding an example execution of the method of FIG. 54. FIG. 12 is an example of a “canvas” which represents the end result of the floor plan being analyzed for tiling purposes. Cassette size may be derived from limitations imposed by the grid/canvas and/or from other predefined parameters, such as “cassette minimal length”.

FIG. 9 is an example of a 2D plan or digital file, describing a floor slab to be populated with safely carried cassettes i.e., such that the load of the cassettes is safely borne (supported by) by structural elements beneath the cassettes. The 2D plan describes wall and supporting elements including precise locations and dimensions thereof (which may be scaled). FIG. 9 may be further pre-processed e.g., as described in FIG. 54. The floor plan of FIG. 9 may, of course, be replaced by a grid-like representation of the same information.

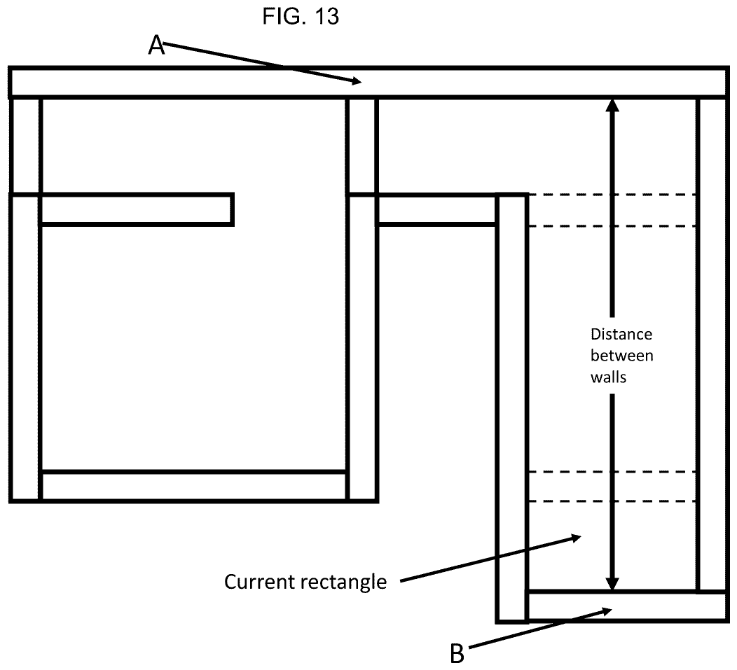

FIG. 13 illustrates a situation in which, for defining a field using the default direction, the conditions in operations 1080, 1090 & 1100 have to be met. In FIG. 13, the bottom horizontal wall is non-structural, whereas the top wall is structural. A non-structural wall will not support the cassette. Furthermore, the distance between A and B is too big, given that there is an upper limit to a single cassette's size.

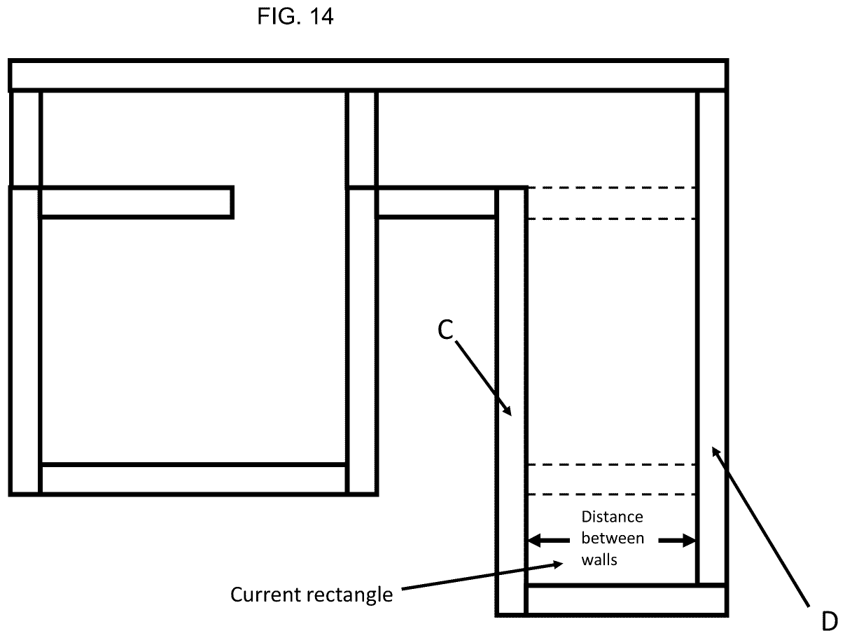

As shown in FIG. 14, when the conditions are not met in the default direction, the perpendicular direction is tested.

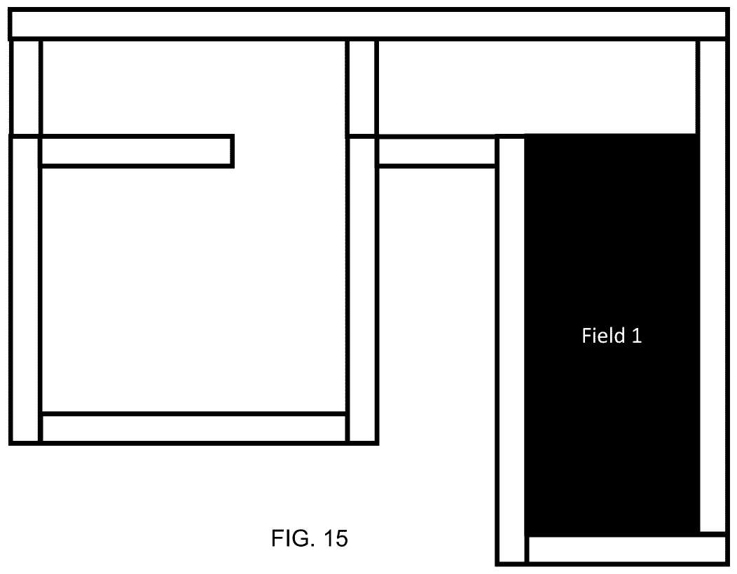

In FIG. 15 a field is defined having the best dimensions possible for the tool to place floor cassettes.

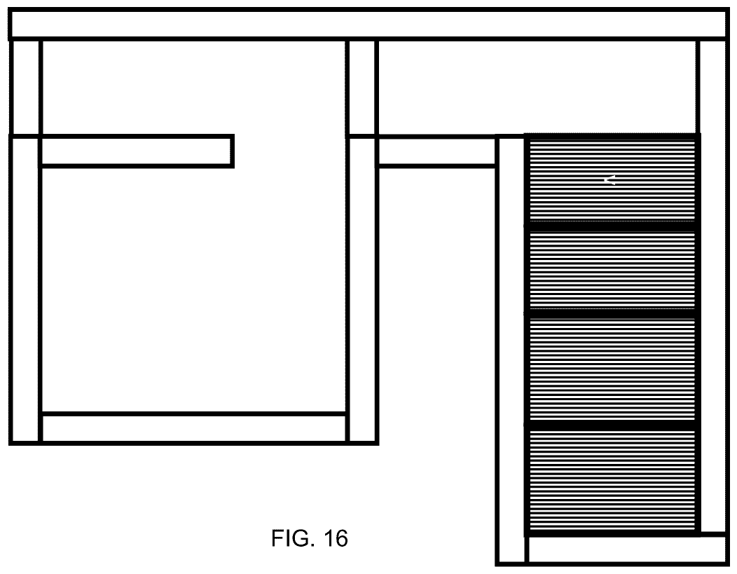

FIG. 16 illustrates digital creation of floor cassettes using input and calculated parameters e.g., using the method of FIG. 37 aka process i. In FIG. 16, a next field is identified, and a method e.g., as shown and described herein populates or attempts to populate this “next” field with suitably sized cassettes.

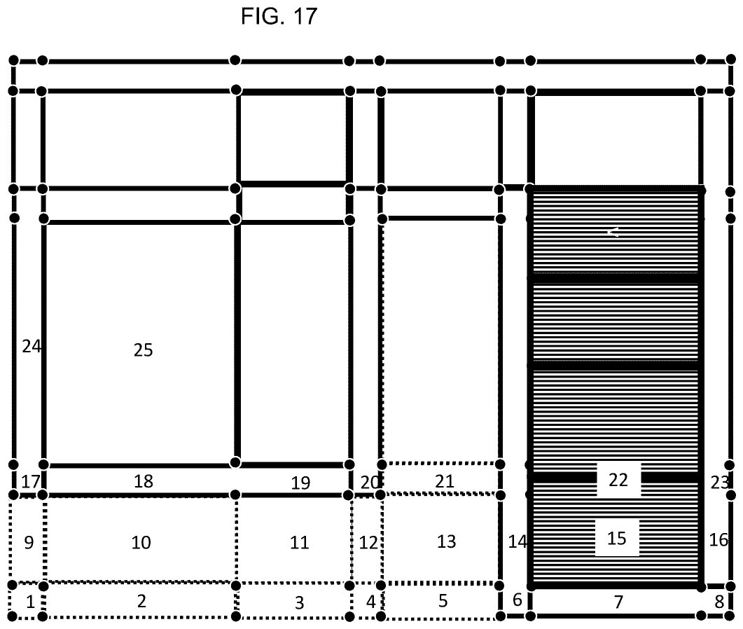

FIG. 17 illustrates grid scanning, which continues to find another field in an interior space unoccupied by cassettes.

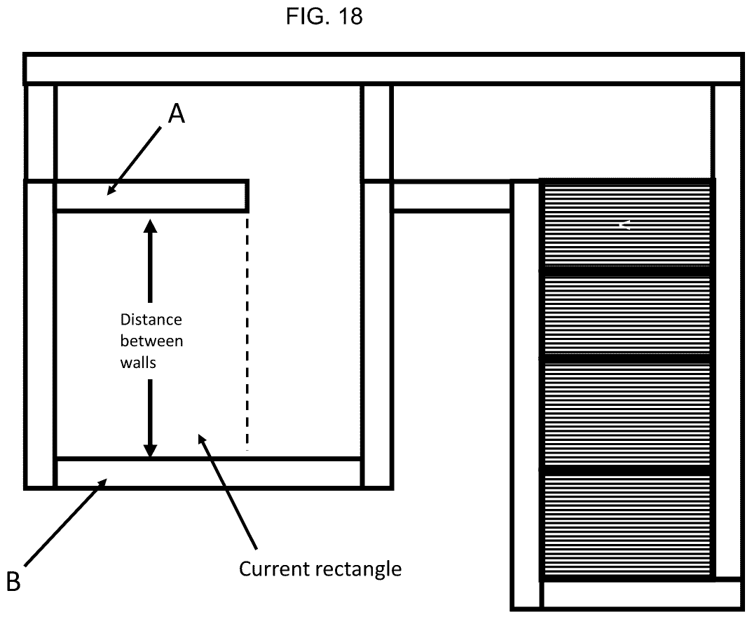

FIG. 18 illustrates a default direction being tested for the conditions in operations 8-10.

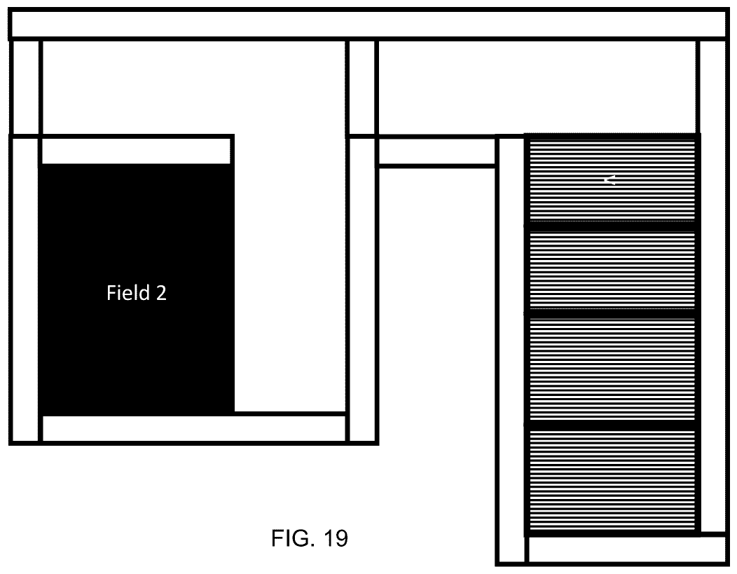

In FIG. 19 a second field is defined.

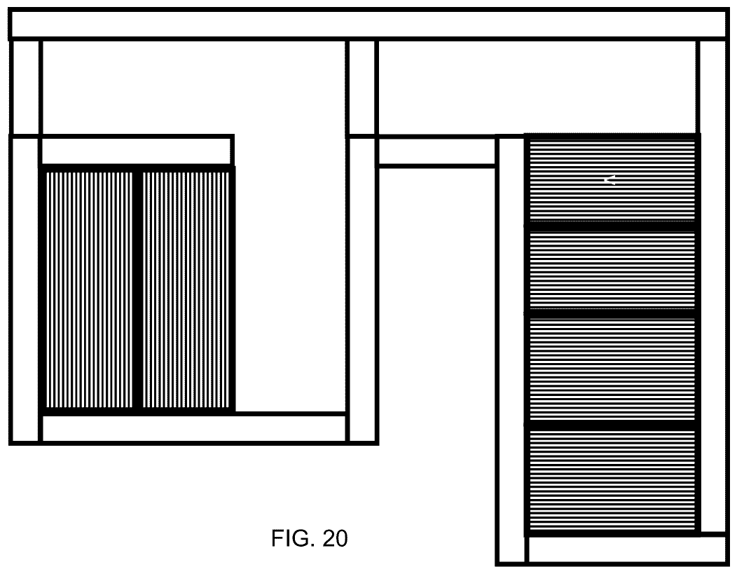

In FIG. 20 the second field's cassettes are placed. Since the structural walls were identified in the default direction, as opposed to the first field, the cassettes' directionality may be perpendicular.

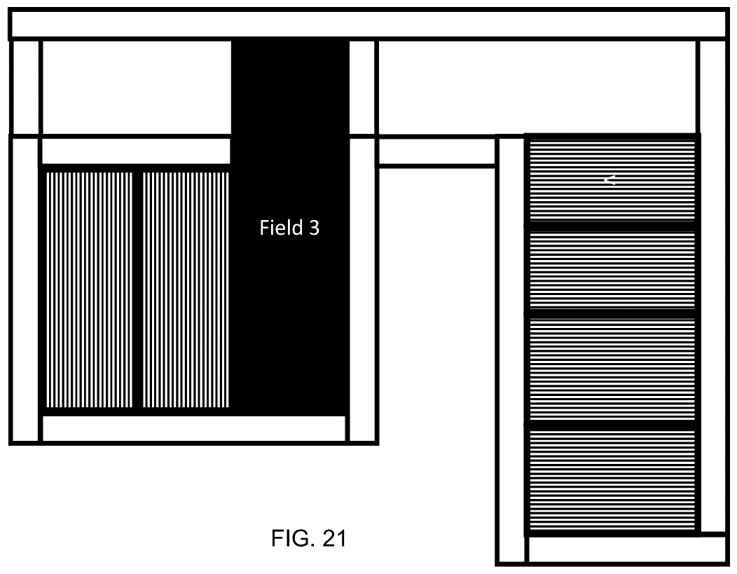

FIG. 21 illustrates third field identification.

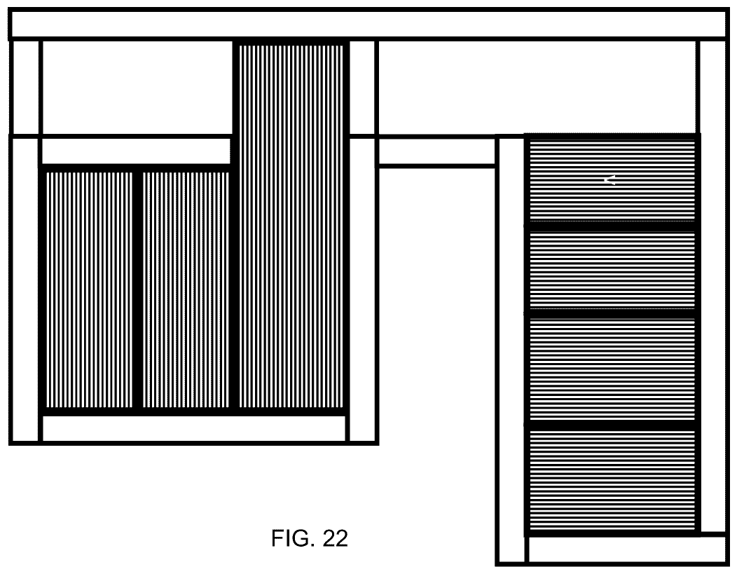

FIG. 22 illustrates third field cassette placement: for short fields even a single cassette may be sufficient.

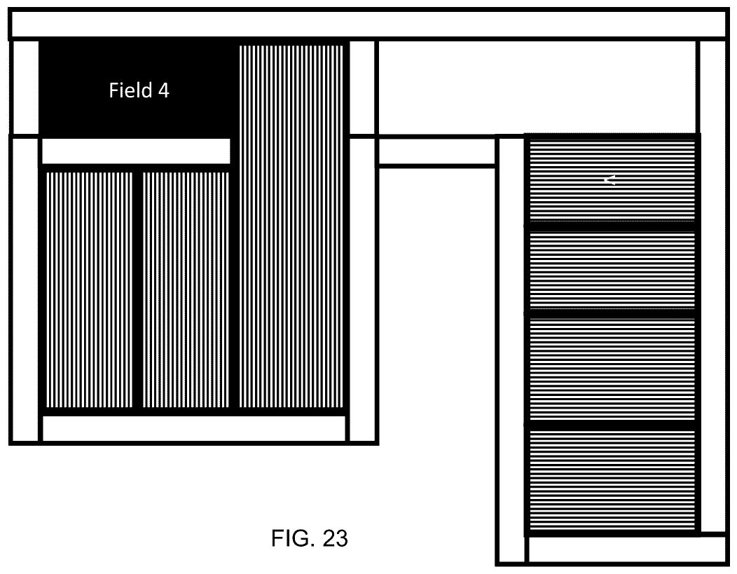

FIG. 23 illustrates fourth field identification.

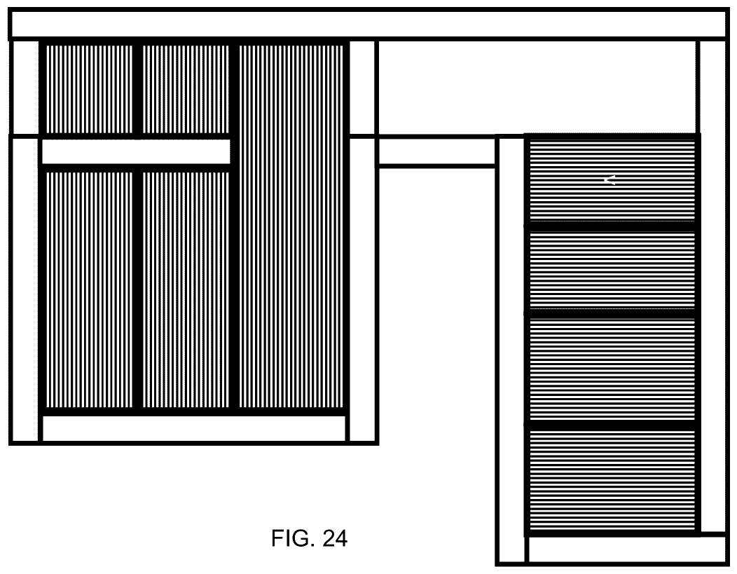

FIG. 24 illustrates fourth field cassette placement.

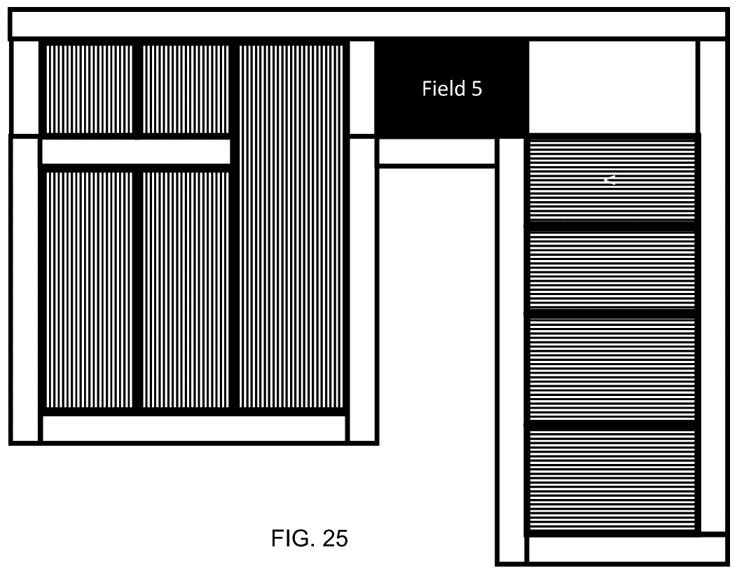

FIG. 25 illustrates fifth field identification.

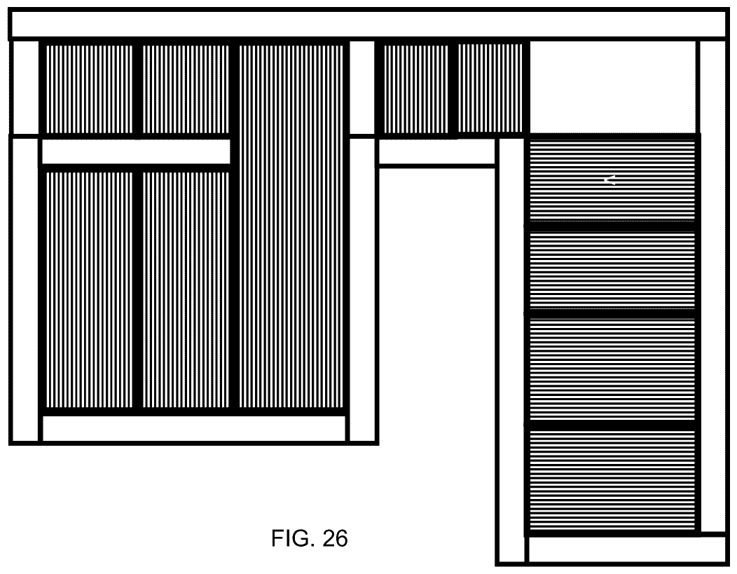

FIG. 26 illustrates fifth field cassette placement.

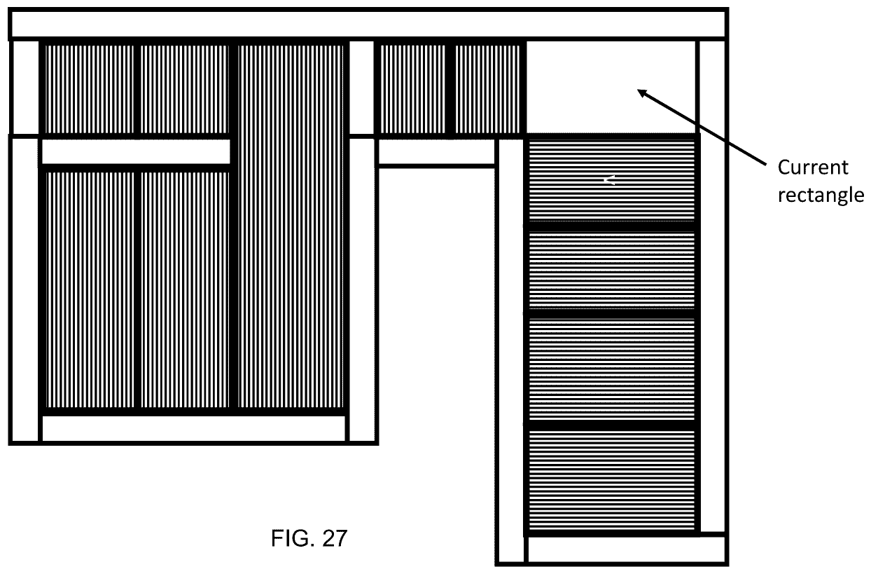

FIG. 27 illustrates a failure: a last area which cannot (e.g., according to certain typically predefined system rules) be used to form a field for cassette placement according to conditions and/or rules defined for the illustrated example.

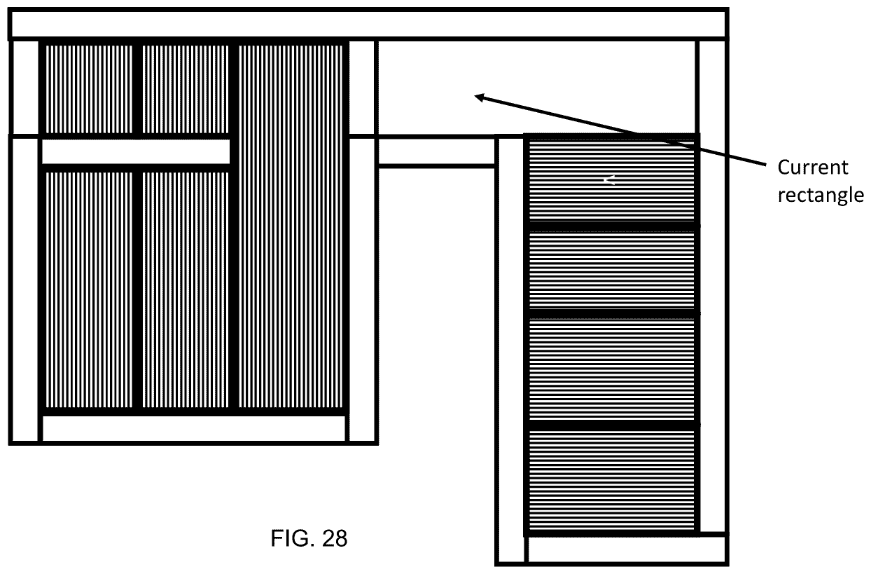

As shown in FIG. 28, at least one previous field is typically removed. Specifically, in the example, the last assignment included adding two cassettes to field 5. The method shown and described herein subsequently determined that the last assignment is to be undone, thus the two cassettes deployed in field 5 in the last assignment, are deleted.

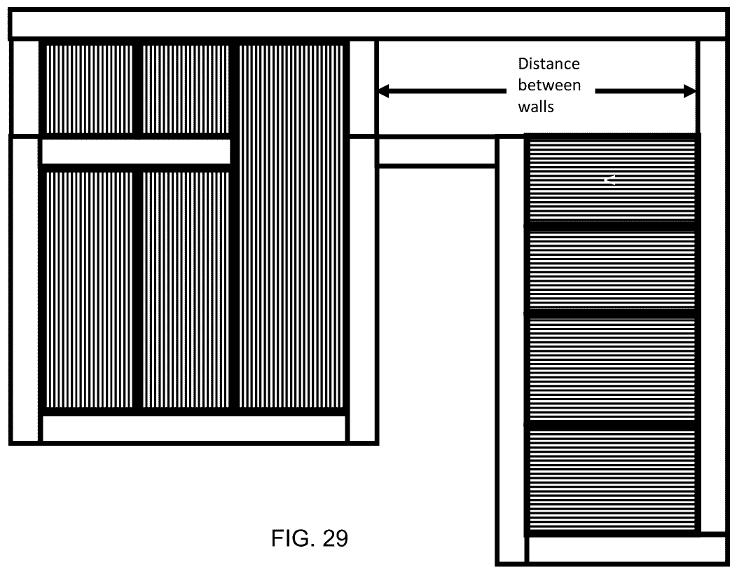

As shown in FIG. 29, instead of the default field direction, the perpendicular direction is also possible, and is tested as an alternative.

It is appreciated that according to certain embodiments, one of the 2 possible directions always succeeds: there is no concern that both directions will fail. This is because the reasons for failure are either absence of supporting walls or dimension limitations. Regarding the first reason, there are always at least two parallel walls capable of supporting cassettes, and, regarding the second reason, dimension limitations may be overcome e.g. if a cassette size of 6×1 meters is too big, 3 cassettes may be used, each sized 2×1 meters.

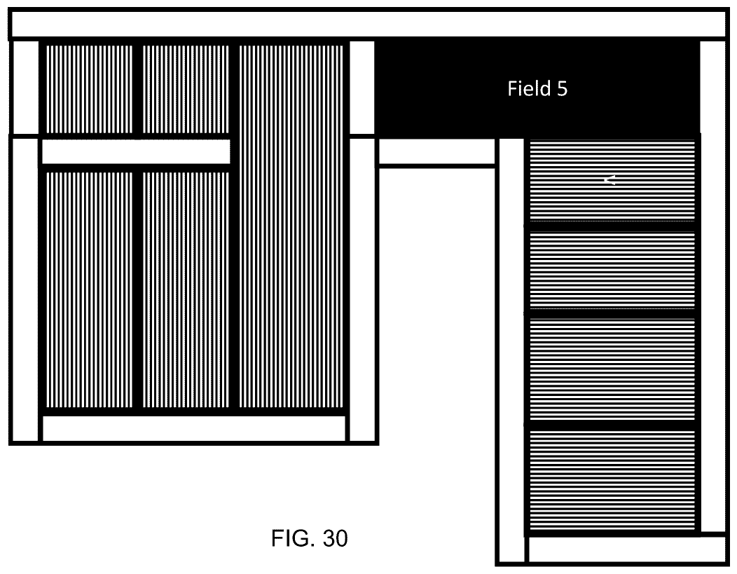

FIG. 30 illustrates a last field identified instead of the previous possibility, which failed.

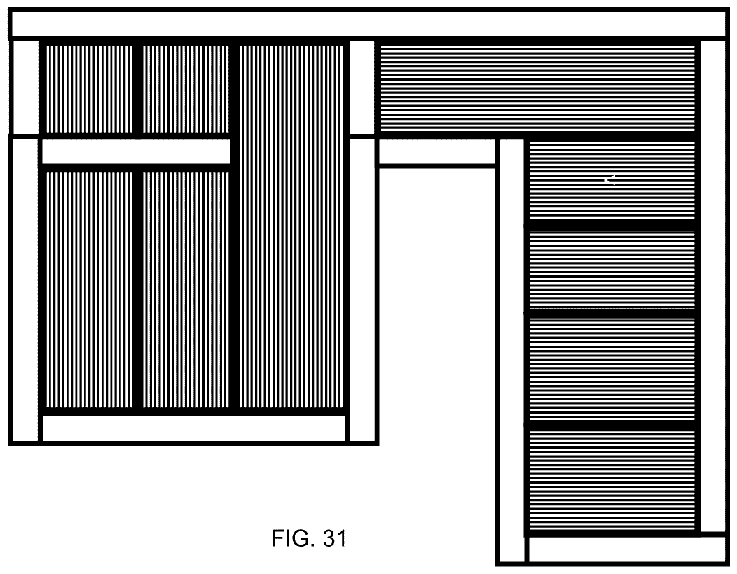

FIG. 31 illustrates last cassettes, modeled and placed to finish the process.

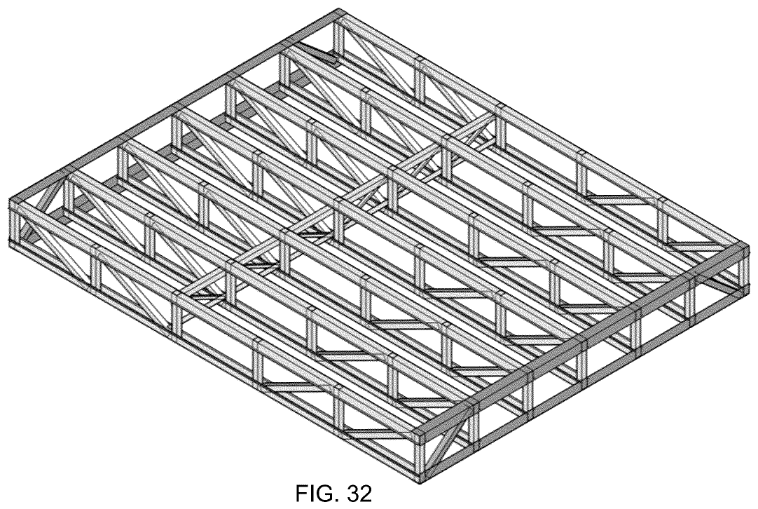

FIG. 32 illustrates a floor cassette including plural inter-cassette and intra-cassette components that typically obtain different sizes and number/s.

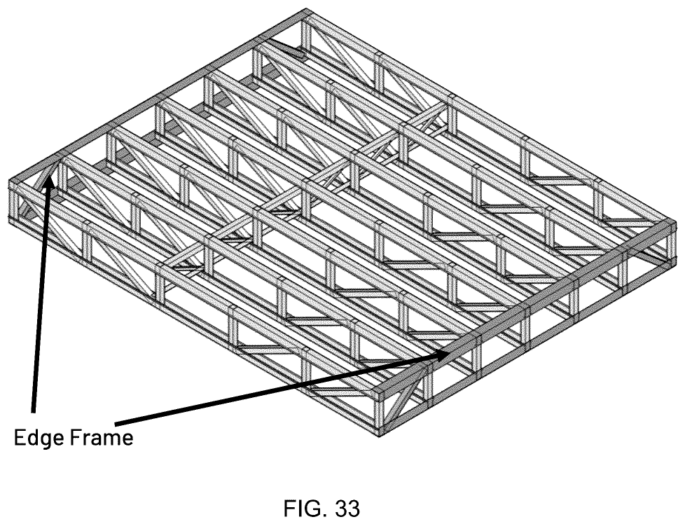

FIG. 33 illustrates an example of cassette components-edge frame.

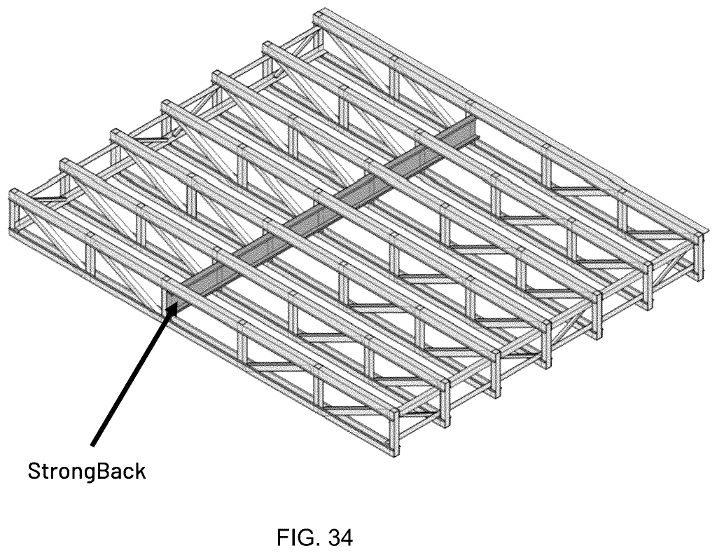

FIG. 34 illustrates an example of cassette components-strongback (any “beam or girder which acts as a secondary support member to existing structure” according to Wikipedia).

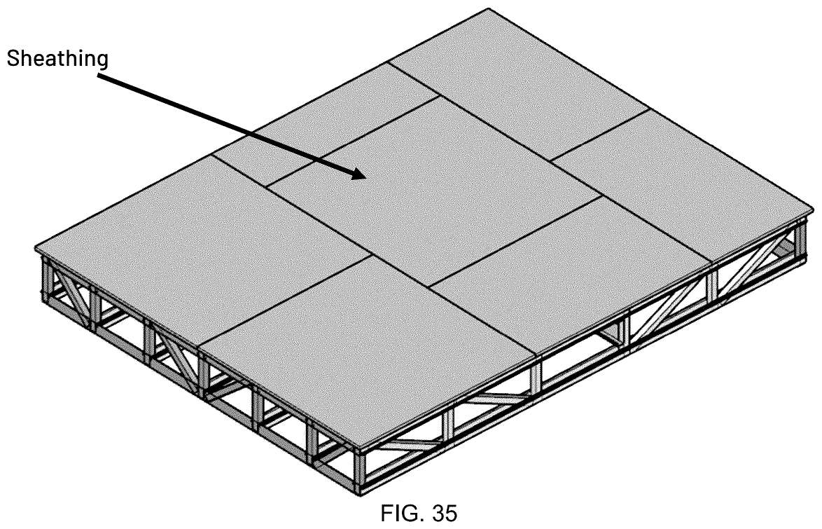

FIG. 35 illustrates an example of a cassette component-structural sheathing. As described above, the Figures, up to FIG. 31 inclusive, are exemplary of execution of a method of tiling which determines cassette sizes. From FIG. 35, the assumption is that the floor cassette has been designed (and perhaps manufactured accordingly), and possible arrangements of cassettes, and connections therebetween, are described. For example, FIG. 35 shows a thin layer including sheet/s of an additional material which may be deployed, providing additional structural support. This is shown, in the illustrated embodiment, to be supplied in fixed dimensions unrelated to cassette size. Several sheets may be required to cover a single cassette. A description of how to use such sheathing in construction is described in https://metcopeland.com/blog/what-is-sheathing-how-to-use-sheathing-in-construction/.

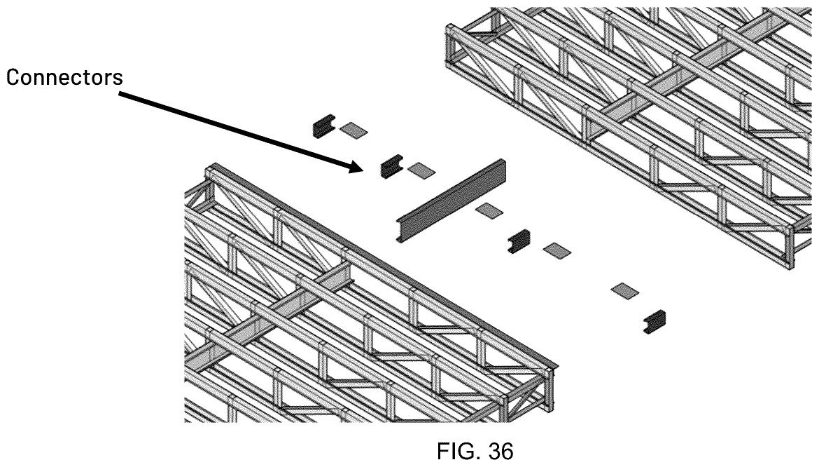

FIG. 36 illustrates examples of inter-cassette connectors which are members which interconnect cassettes.

FIG. 37 illustrates an example “cassette placement” process (aka process ii) that may be used to fill fields with properly sized (customized size) cassettes. All or any subset of the operations of FIG. 37 may, for example, be used to implement operation 1160 of FIG. 2B. Regarding FIG. 37, operation 2010, input to the flow, typically includes all or any subset of the scalars shown.

The term “field width” (“width” in operation 2000) typically refers to a distance between two structural elements on either side of a field. Generally, each field may comprise a rectangular area between two structural elements, such that floor cassettes populating the rectangular area will be supported on two opposite sides by the two structural elements. Typically, several, e.g., 3-10, cassettes are used to tile each field.

Overlapping wall length may comprise the length of the field which runs between both of the structural elements, not just one of them.

Remaining field length may refer to whatever portion of the overlapping wall length remains uncovered by cassettes, and may be interchangeable with the term “overlapping wall length”.

Input field length: an input parameter to the flow which measures the dimension of a field other than the known width of that field (which is typically the distance between the two structural elements which support the field in question.

Typical cassette_length may comprise a predefined starting point value for a “current_cassette_length” variable, an initial value (e.g.: 2.00 meters) which is typically modified by the method of FIG. 37, e.g. by trial and error, depending on whether attempts to populate a given field with cassettes of a given length succeed or fail. The final cassette length for a given field is the value of “current_cassette_length” when success is achieved.

Typically, a “minimal cassette length” is stored in the system, referring to physical limitations e.g., pertaining to production of the cassette. For example, if each cassette must comprise at least two trusses in parallel (no spacing), and each truss is at least T meters long, the minimum cassette length is at least 2 T.

Typically, no maximal cassette length is stored in the system: even if, for some physical reason, there is a maximum limit, then if the flow of FIG. 37 assigns a length to a cassette which exceeds this maximum, then this assigned length may be divided into (say) two, or the initial value of FIG. 37's counter may be modified, or set as follows:

counter=int([field_length]/[max_cassette_length])+1,
where int(X) is the integer part of X.

For example,
a. if max=3 and field_length=5, instead of setting the counter to 1, the counter may be set as follows:

counter=int(5/3)+1=2.
b. if field_length=2, counter may be set to int (2/3)+1=1.

According to certain embodiments, some fields in a floor slab are populated in the default direction, and others in the opposite direction. Example: a certain floor slab aka floor plan has 10 pairs of structural elements running north to south. The methods of FIGS. 2A-2B and 37 populate the fields in between the first 6 pairs, along the default direction. The 7th field, in between the 7th and 8th pairs, fails for the default direction. The method may, according to certain embodiments, try to populate field/s from field 7 onward from east to west, without deleting the 6 fields successfully populated using north-south direction, resulting in a floor slab including some fields populated north-south, and other fields populated west-east.

According to other embodiments, all fields in a floor slab are populated in the same direction.

It is appreciated that floor cassette's structural properties may be direction-specific, hence are not preserved if the floor cassette is rotated. For example, a square cassette whose structural support is designed to be from north and south, cannot safely be rotated by 90 degrees to an orientation in which the structural support is from east and west. Therefore, a sequence of direction-specific cassettes populating a field typically do not have mixed orientations: instead, all cassettes in the field typically have the same orientation.

It is appreciated that, typically, floor plans including floor cassette size and/or direction of population, may vary between projects, buildings and floors, although, due to operational considerations, it is sometimes desirable to reduce the number of cassette types within a project e.g. by reducing the number of different floor cassette sizes.

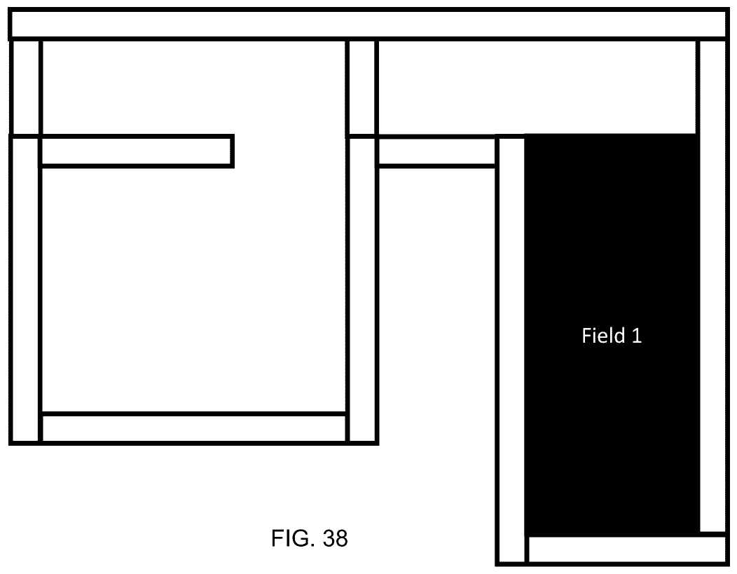

FIG. 38 illustrates a field identified e.g. in the main process of process i or ii. According to any embodiment, when a field is defined between first and second parallel structural walls, the width of the field is the distance between the walls, and the length of the field is the length of the portion of the first wall that faces a portion of the second wall: it is appreciated that certain portions of the first wall may face portion/s of the second wall, whereas other portions of the first wall may not face any portion of the second wall. In FIG. 38, the top portion of the right-hand wall bounding the field does not face any portion of the left-hand wall bounding the field.

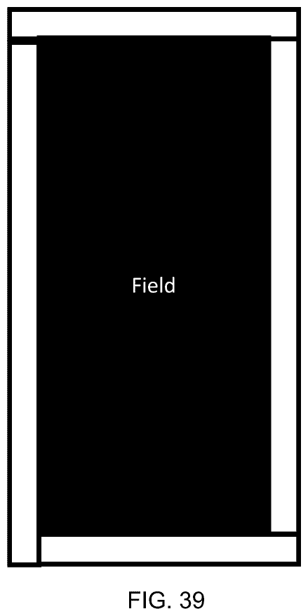

As shown in FIG. 39, each field has its orientation and dimensions, which influences the number size and orientation of the cassettes.

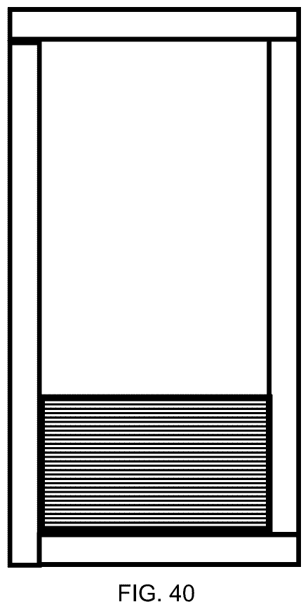

FIG. 40 illustrates first cassette placement, in which the cassette's length is default, and the cassette's width is identical to the field's.

The cassette depth may be uniform over all cassettes in a given building project including plural buildings. For example, the maximum building height and the number of targeted floors may determine the typical apartment/room height. Coupled with structural considerations, the floor (or ceiling) cassette depth may be determined, e.g. as part of an interior cassette design determined at this stage including computation of trusses and/or other supports. There may be restrictions regarding minimum depth e.g. as a function of minimal truss dimensions and/or minimal design that can support structural considerations.

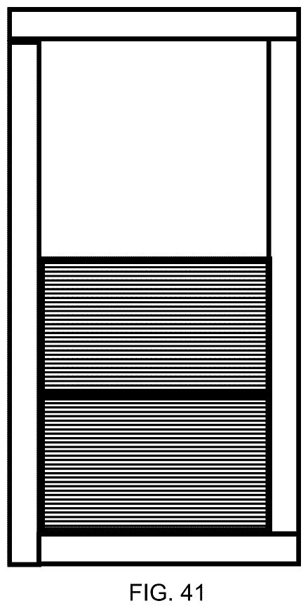

FIG. 41 illustrates second cassette placement.

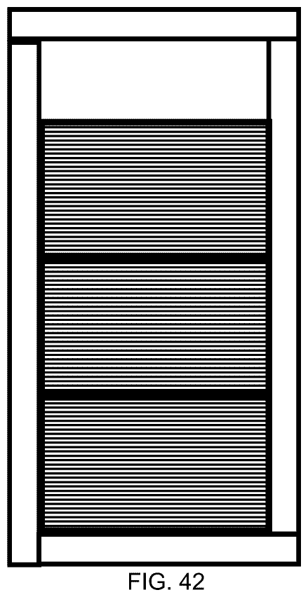

FIG. 42 illustrates third cassette placement.

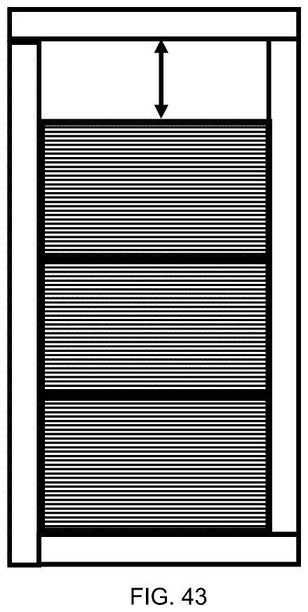

As shown in FIG. 43, the remaining length is long enough for cassette placement.

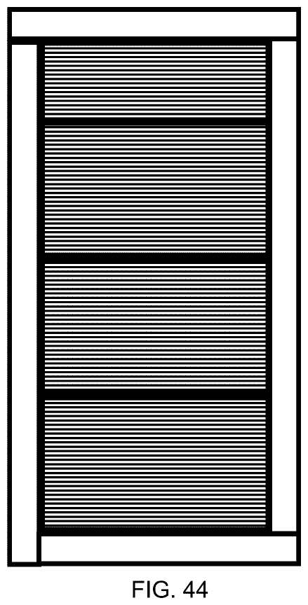

FIG. 44 illustrates placement of a cassette which may be smaller than a typical cassette e.g., may be smaller than the first, second and third cassettes, but is typically larger than a minimum allowed length (which may be a predetermined parameter).

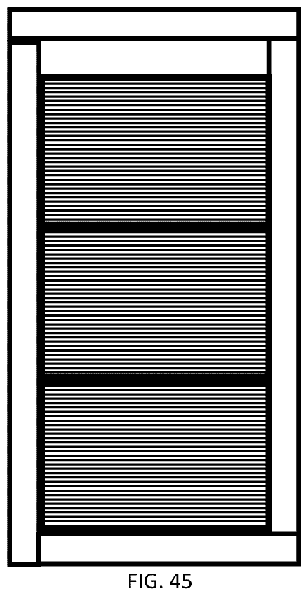

As shown in FIG. 45, the remaining length might be too short.

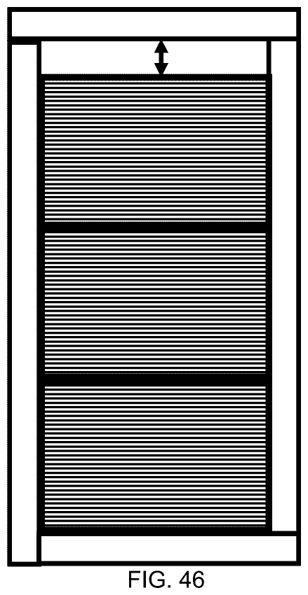

As shown in FIG. 46, the first possibility becomes irrelevant.

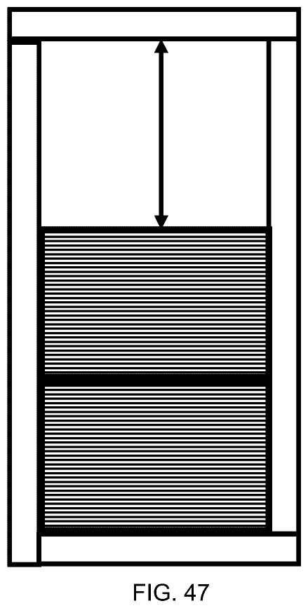

As shown in FIG. 47, the last cassette is deleted

As shown in FIG. 48, two, typically equally sized, typically shorter than typical cassettes are placed, instead of a typical cassette and a short cassette.

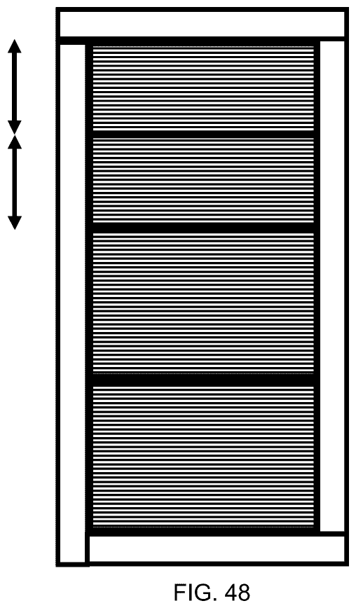

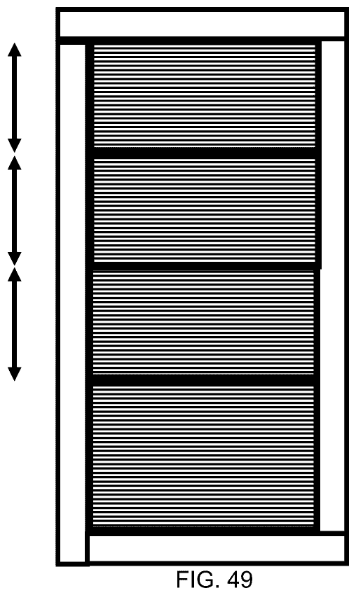

As shown in FIG. 49, in the event that the two cassettes are also too short, an additional cassette may be removed and resized: this may be done repeatedly e.g., many times. According to one embodiment, three, typically equally sized, typically shorter than typical cassettes, may be placed instead of a typical cassette, and two short cassettes, and so forth for 4, 5, etc.

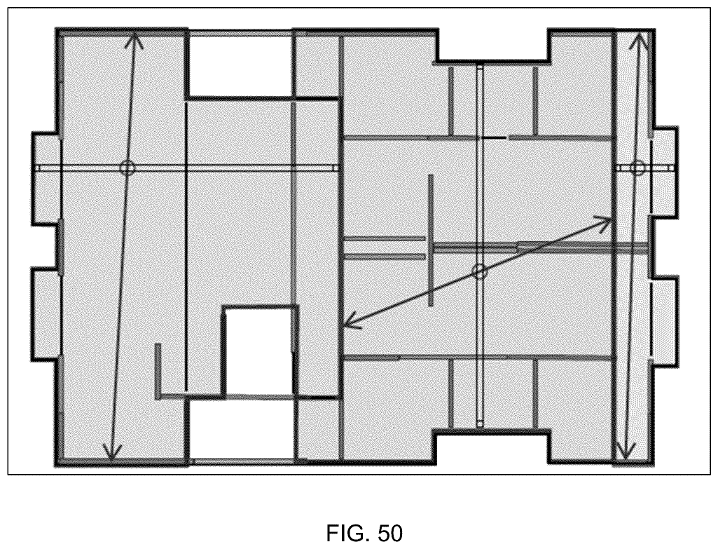

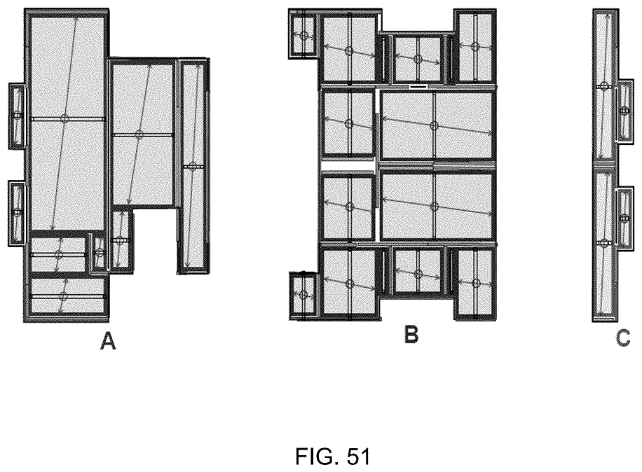

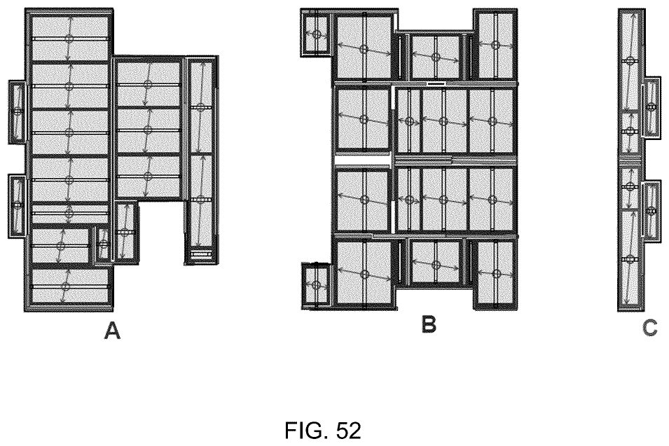

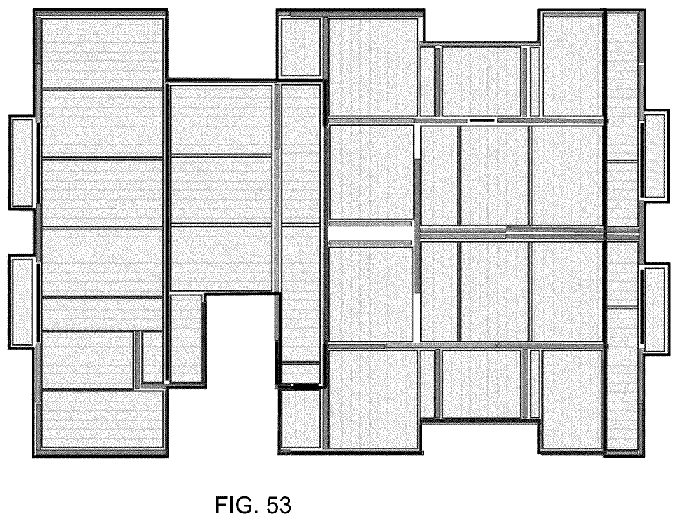

As shown in FIG. 50, an entire structural floor may be modelled using the tool, in parts or as a whole. In FIG. 50, the input may comprise a floor slab 50 and its architectural and/or structural elements. In FIG. 51, a tool such as that shown and described herein, divides or partitions into fields, typically logically, not spatially. In FIG. 52, subdivision of fields and floor cassette placement may occur, and an output shown in FIG. 53 shows a floor with structural cassettes aka floor cassettes and elements. As shown, some cassettes are arranged along one dimension (shown as the horizontal dimension of the page), and other cassettes are arranged along another dimension (shown as the vertical dimension of the page).

As shown in the real-life example of FIG. 51, any floor size and shape may typically be modelled.

As shown in FIG. 52, field- and cassette sizes may be flexible. Any suitable range of cassette sizes may be employed e.g., as a function of physical dimensions of the house/apartment/room. For example, the cassette size may range from about 20% to about 50% of a room area (which may be 6 or 8 or 10 or 12 or 14 or 16 or 18 or more square meters).

FIG. 53 shows a final outcome (real project) with floor cassettes and sheathing on top.

It is appreciated that a modelling process may include an input of an architectural floor having no structural details (e.g., element A in FIG. 1). The output (e.g., element b in FIG. 1) may include one or (more typically) plural cassettes with additional components e.g., as shown in all or any subset of FIGS. 33-36. The tool automates this process.

Certain embodiments provide an automation process for structural floor modelling. Any individual operation may be modified or omitted to fit different design, fabrication, or assembly techniques, e.g. as described herein.

A simplified flow-chart illustration of operation of an automation tool is provided in FIG. 2 aka process i.

FIGS. 3 and 4 respectively show an example of a building having a single floor before and after manual placement of the architectural floor slab for the next floor J; the tool may for example be initiated after the architectural floor has been placed. The process herein may digitally produce and place ceiling cassettes with all the required components inside and/or between the cassettes them and (e.g., FIG. 5) may also provide automation for the addition of more relevant components such as sheathing (e.g., FIG. 6).

There may be system limitations and/or rules for floor cassettes placement and/or sizing direction. These rules may be related to manufacturing capabilities and limitations (e.g. maximum size of the panel which can be handled), and/or to storage and transportations limitations (e.g., techniques for storing manufactured walls, vehicle (truck) dimensions, road lane/height restrictions), or on site assembly considerations (e.g., maximum weight of the wall to be lifted and deployed, balance/compromise between smaller cassettes and the amount of work required to connect them together for covering a floor area), local code considerations (e.g., the city or state may dictate some design restrictions on the floor area size, as derived from the lot size and neighborhood area as street/sidewalk and nearby houses which dictate minimum distance of the constructed building from its surroundings). This array of floor components is typically structural, typically being expected to bear the load of the weight of everything that may be on that floor. For this to happen, the floor cassettes in each architectural floor N in the building, typically need to be supported by the walls in the architectural floor N-1.

For example, FIG. 7 shows a side-view of a load bearing wall having a structural ledger angle. This angle may be installed on a load bearing wall. In order to place a structural floor cassette in its place, the cassette typically needs to be supported by parallel ledger angles that are in front of each other and are at least as long as the cassette. Less than all the walls in a building are load bearing, thus the planner of the building typically needs to create a sufficient number of (say) cassettes and/or to add other structural elements, such as structural beams, in order to make it possible to deploy a structural floor on top of the walls. The cassettes may have predefined size limits in order to provide the floor with given structural properties.

Thus, the process of modeling a floor cassette is not straightforward, and requires knowledge, experience, and effort.

FIG. 8 onwards provide a visual description of the process that the tool automates, and are thus useful in understanding certain embodiments of the method shown in FIGS. 2A-2B.

FIG. 2A operation 10: The user typically selects a floor area or slab to define the input and starts (operation 2) the automation tool.

This may be done for more than one floor of a project: see e.g. floor n in FIG. 8.

Operation 1020 is optional, since provision of trusses is optional. The term “truss' here refers to any elongate structural member which includes metal or timber to form triangles, typically lying in a single plane: due to their shape, triangles cannot be distorted by stress. Cassettes often, but not necessarily, include trusses. Typically, trusses are oriented perpendicular to the parallel walls or beans on the sides of the field which are the ones which will carry or support the cassette, thus if the walls/beams are vertical in orientation, the trusses are perpendicular to the wall direction, hence vertical, and vice versa.

The tool e.g. as per the method of FIGS. 2A-2B then first uses the walls below—in floor n-1 (e.g., FIG. 9). The tool typically creates a temporary digital grid (e.g. FIG. 10, and process i aka FIGS. 2A-2B, operation 1030) of long lines that are co-planar to each wall on both of the wall's long sides. The grid may also include short lines that are co-planar to at least one wall on both of the wall's short sides e.g., if that wall's short sides are exposed or are visible, even after the building has been completed. This yields a grid of rectangles. The junction points of every two lines may be saved in a data table for further use (e.g., FIGS. 2A-2B, operation 1040).

It is appreciated that the grid is typically not a matrix of equally sized and/or equally spaced rectangles. The grid forms rectangles which are not normally equally sized, and not normally equally spaced.

The lower bottom point, for instance, may be selected to represent the origin (0,0) and the saved points may have corresponding values:

$$Points = \{ ( x 1 = 0 , y 1 = 0 ) , ( x 2 = 0.5 , y 2 = 0 ) , ( x 3 = 4 , y 3 = 0 ) ... ... ... ... ... ( x 31 = 6.5 , y 31 = 5.5 ) , ( x 32 = 7 , y 32 = 5.5 ) \}$$

Every four points create a rectangle. Every rectangle may represent an area which has a different content. FIG. 11 shows possible rectangles' content for the given example: a given rectangle may for example represent any of the following:
Non-structural wall
Structural wall
Interior space
Exterior space
Structural beam.
or a rectangular portion of any of the above.

Typically, each point has a “type”, depending on the perpendicular lines which intersect to yield that point. Some sets of four points may form an area deemed meaningless e.g., portion of a wall which may not be used in computations shown and described herein or an area which does not need to be populated by floor cassettes. If four points merely cover a portion of an internal wall, this is discoverable by looking at the point of the center of the rectangle, and using the building's floor plan/digital file to determine whether this point is in a wall or in in a free space between walls. The center, given coordinates of four points which are (a,b), (a,b+y), (a+x,b+y), (a+x,b) is defined as (a+x/2,b+y/2).

It is appreciated that buildings may have a floor plan e.g., for a floor slab under a floor slab being designed, which indicates inter alia locations and dimensions of structural elements such as structural walls, in a known and machine-readable protocol or format.

In operation 1050, the system typically, e.g., as shown in FIG. 10, is configured to generate a grid of lines and dots based on positions of structural elements e.g., wall/beam positions. Eventually, the sides of each rectangle in the grid include various types of walls. One rectangle may have all sides non-structural (for example, a region in a living room which has decorative/non-structural half-walls, merely to define a space for sitting down and watching TV). This type of rectangle cannot be used to define a field in which cassettes are to be supported by all rectangle edges or sides. Another rectangle may have two opposite structural sides and two opposite non-structural sides. A third rectangle type is three non-structural sides, and a fourth structural side, etc.

Some types such as an interior portion of a wall may come up using the grid structure as a possible rectangle to be covered by a cassette even though this is not a target area to be covered. Therefore, the system may target or handle only areas which are “real” e.g. need coverage by cassettes e.g. bound an interior space as opposed to logical rectangles which are a byproduct of the flow but do not need to be covered by cassettes. Even given real areas, it is appreciated that each cassette typically needs structural support from below as described elsewhere herein.

Typically, the tool typically identifies every rectangle for its content (e.g., FIGS. 2A-2B-operation 1050). This identification is done according to properties of the objects in the model or the properties of the objects in the neighboring rectangles e.g. as per the method of FIG. 54. This operation is useful because the floor cassettes typically need to be placed on interior space only, and their orientation is determined by the spaces' size and structural elements around them. Next, the tool may start scanning the rectangles typically in a predetermined order, or using a predetermined pattern. For instance, FIG. 12 shows the numbering of rectangles by which the tool scans horizontally from the most bottom left to the top right of the model. The tool thus passes from rectangle to rectangle e.g., until the tool finds a rectangle that was identified as an interior space (e.g. FIGS. 2A-2B-operations 1060, 1070).

Next, the tool may test this interior space to try and define a “field”. A field may include a first rectangle, enclosing or circumscribing one or more smaller interior space rectangles, that may be defined by the grid tool e.g., as shown in FIG. 10 e.g., for initiating floor cassettes in a given area. The method of FIGS. 2A-2B describes when a field is defined; operation 1150 indicates that the next operations are those of FIG. 37, e.g. by calling the method of FIG. 37 as a subroutine used by the call of operation 1150. After the method of FIG. 37 has been performed, the flow may return to operation 1150 and continue to operation 1160 and so forth.

After operation 7 has been confirmed (e.g., confirmed there is no cassette in a given rectangle of interior floor space), the tool typically checks to see if the current interior space has two parallel structural walls around it. The direction of the walls may be horizontal or vertical (on the top view floor plan). The default direction (e.g., “north to south”, assuming that the orientations of the walls e.g. “north-south”, “east-west” is known to the system) may be given as an input when the tool is initiated by the user. It is appreciated that north, south, east, and west are not used herein as geographically associated orientations, and instead are used merely to distinguish between the two perpendicular axes which are normally relevant to an architectural structure, which may or may not actually be oriented to north, or south, or east, or west, respectively.

If parallel structural walls are identified in the default direction (e.g., FIGS. 2A-2B—operation 1080) the tool determines whether their distance is within a given range (e.g., FIG. 2—operation 1090), also typically predetermined by the user. This distance typically affects the fabrication, assembly, and structural integrity of the floor, thus the range may be an expert determined value stored by the system. If the walls' distance is within range (e.g., FIG. 14) the tool may verify that the current space does not already have cassettes modeled therein. If the space obeys all the rules (e.g., of operation 1080) and/or operation 1090 and/or operation 1100), a field may be defined (e.g., FIG. 15) which allows covering that space with cassettes (e.g., FIGS. 2A-2B—operation 1150). The cassette creation and placing (e.g., FIG. 16, FIGS. 2A-2B—operation 1160) may also have different details that may need automation e.g., as described below. Typically, the cassette itself is not a block of solid material and instead e.g. as shown in FIGS. 5 and 3-4, has its own interior design (e.g. how many trusses, angles, connections, etc.) which typically is determined, typically automatically, once the cassette external dimensions are known. A cassette may include a layer of trusses and other layers (e.g., fire insulation and/or structural sheathing layer), aspects of which may also be determined once external dimensions are known.

In some cases, the first direction tested by the tool to define a given rectangle as a field may be compatible e.g., may “pass” operation 1080 or 1009 or 1100 in process I aka FIG. 2. in a system which has three rules represented respectively by operations 1080, 1090, 1100. In this case, a field may be defined because the load of the cassettes which may cover that field, may be safely carried i.e., supported by the structural walls of the first direction.

In other cases, the first direction tested by the tool to define a field may not be compatible e.g., may “fail” operation 1080 or 1090 or 1100 in process i aka FIG. 2. In this case the tool may try the second, perpendicular direction (e.g., FIGS. 2A-2B-operations 1110 and 1140)). In this case too, a field may be defined because the load of the cassettes which may cover that field, may be safely carried i.e., supported by the structural walls of the second, perpendicular direction.

FIGS. 13 to 26 show a repeating process, in which a tool goes from one rectangle to the next, defining fields e.g., according to the process shown and described herein, and placing cassettes.

When fields are identified and cassettes placed up to a certain point, the flow may lead to a situation in which there is no possible way to create a field for a given area. FIG. 27 shows a situation in which the last rectangle of the example floor cannot (e.g., according to certain typically predefined system rules) create a field e.g., because there are already cassettes around it in both directions.

In such cases, the tool may delete the last field's cassettes and try to redefine its field in the perpendicular direction (e.g., FIGS. 2A-2B—operations 1120 and 1130). More than one iteration may be performed, according to certain embodiments, such that when a field cannot (e.g. according to certain typically predefined system rules) be created, all previous fields that were completed may eventually be erased, and the tool redefines one or more of, or even all of, those fields, in order to solve the problem.

As appreciated, by comparing FIGS. 26 and 27 (or by comparing FIGS. 21 and 22), in the example, the cassette sizes which were being used in FIGS. 21 and 26 were too short, or too small, hence did not fit the fields which were to be tiled/populated. Therefore, a size modification occurs, in the illustrated example, and as shown in FIGS. 22 and 27.

FIGS. 27-31 show an example which encounters a problem in creating the last field, and a solution involving deleting and redefining the previous field.

FIGS. 32-36 illustrate an example of a steel frame floor cassette and its components. A building's space/s' size and orientation may change from project to project and/or between companies (e.g., between end-users of software constructed and operative to perform the process shown and described herein). The structural requirements may also change from project to project and/or between different jurisdictions. This leads to a large variety of floor cassettes, which may need to be modeled from scratch every time e.g., per project. Thus floor cassettes and their components e.g. as shown in the figures, may, according to certain embodiments, have a large, and practically endless variety.

Processes for modeling and placing these structural components may be defined to cooperate with the process of process i herein.

For instance, a process may be provided which sizes and places cassettes to fill a given field, according to predetermined properties from the user and/or from the tool. An example of such a sub-tool's process is shown in FIG. 37 aka process ii. Typically, the tool first receives a defined field's size from a main program e.g., the process of FIGS. 2A-2B or process ii. Additional input describes the size limits and requirements of a single floor cassette (e.g., FIG. 37 operation 1010).

The tool may then start placing cassettes having a typical length (e.g., FIG. 37 operations 1020, 1030, 1040) e.g. as shown in FIGS. 40-42. When reaching the last remaining portion of the field, if the portion's length is longer than the minimal cassette length that is defined (e.g., FIG. 37 operation 1050)—the tool may place a last, shorter cassette to fill the gap (e.g. FIGS. 43 and 44).

In the illustrated example, the remaining length in FIG. 47 is too long, whereas the remaining length in FIGS. 46, 45 is too short. Thus in FIGS. 45 and 46, there is not enough room for another cassette to be tiled within the available space, hence size is adjusted, and cassettes of a new size are used instead for tiling or populating the field in question.

Generally, if the remaining field length is shorter (e.g., FIGS. 45-46) than the minimal cassette length allowed (e.g., FIG. 37 operations 1050 and 1060), the previous cassette may be removed. If the cassette-free length is now sufficient to accommodate two cassettes equally sized and longer than the minimal allowed cassette length, two such cassettes may be provided (e.g., FIGS. 47 and 48). This process may repeat itself thereby to remove and resize additional (three, four, five, or more) cassettes (e.g., FIG. 49) until the field is emptied and filled with typically equally-sized cassettes of suitable dimensions (e.g. longer than the minimal).

It is appreciated that the tool shown herein is very flexible in its capabilities-allowing floor cassette modeling for floors with different shapes and sizes typically in a matter of seconds, as shown e.g. in FIGS. 50-53.

Certain embodiments herein include covering a floor or floor plan with floor cassettes including determining size and/or directions. The floor plan/floor typically comprises a horizontal leveled structure constructed from smaller multiple floor cassettes. The floor cassette may be fixed in dimensions and may be reused to tile or populate the floor. Walls, which may be prefabricated, are then installed atop the floor. Each cassette is typically a mechanical structure designed for distribution of forces and moments: the walls may impose design considerations on the cassettes, especially if the walls or cassettes serve as load barriers e.g. rather than (just) for space segmentation. The process herein may include an iterative design process e.g., as described herein, which outputs a recommended size of cassette and a tiling plan.

It is appreciated that, typically, there is no cassette atop a beam e.g., as shown in FIG. 5, in the room closest to the bottom of the page, e.g., because the cassettes are structural, as are the beams. More generally, it is typically the case that cassettes are placed on interior space only, and not atop walls, or exterior spaces, or beams.

An illustration of walls, both structural and non-structural, and a structural beam, is shown in FIG. 11. Every four points create a rectangle aka logical rectangle which represents a physical rectangular area which may, (as shown in FIG. 11), comprise a non-structural wall or a structural wall or an interior space or an exterior space or a structural beam.

A “next” logical rectangle may be defined, in accordance with a predetermined ordering e.g., by scanning horizontally from, say, bottom left to top right.

According to the embodiment shown in FIG. 15, a “field” typically lies between parallel portions of structural walls, and each field's length is the length of each of the structural walls' portions which lie opposite one another or “overlap” (as opposed to those portions of one structural wall which do not lie opposite (parallel to) any portion of the other structural wall defining the field.

Cassettes may include steel panels, typically having an edge frame and/or strongback and/or structural sheathing e.g., as shown in FIGS. 33-35—which, together, may form a structural floor.

A field may comprise a rectangular area which, typically is covered by whole cassettes, e.g. by two or three adjacent cassettes (as opposed to non-field areas, which may also be rectangular, yet are (eventually) covered by at least one non-whole cassette such as an area including half of a first cassette and half of a second, adjacent cassette, or such as an area including half of a first cassette, a whole second cassette adjacent to the first, and half of a third cassette adjacent to the second).

Thus, when performing the method of process i for grid creation, operations 1030, 1040 may include saving (x,y) coordinates of each junction between two (or more) intersecting walls on floor n-1, e.g. as shown in FIG. 10. FIG. 1B (vs. FIG. 1A) is an example output of the method/tool for a single room, whereas FIG. 5 (vs FIG. 4) shows the total output of the method/tool for all rooms on the floor.

Process ii shows a method for field creation and cassette placement. This may be used to implement operation 16 in process i (grid creation).

Lines (=) may be used to represent cassettes supported by vertical supporting walls.

According to certain embodiments, the method of FIG. 2B identifies an area between two parallel supporting structural elements whose distance from one another is suitable to enable this pair of elements to support a floor slab, and seeks to populate this area (e.g. field/s). Typically, no prefixed lengths of cassettes are predetermined, and, instead, cassette dimensions per floor plan are determined only once the method of FIGS. 2A-2B has been completed. Typically, cassettes may be manufactured on demand in almost any size, however the method herein reduces the number of variants within a project (e.g., by populating areas between two structural elements with equally sized cassettes. This simplifies the operational process e.g. because the machine can be programmed, once, to produce 26 (say) walls of the same type, or plural cassettes all of the same dimensions, and because a reduced number of variants translates to batch delivery to a construction site, rather than individualized transport of a large number of unique variants, each used in only one building location.

The method of FIGS. 2A and 2B may be called or used once per floor slab, when a building's floor slabs are being designed, in the design phase, where “floor slab”, e.g. as in FIG. 8, typically refers to a floor of a complete building level e.g. of the building's first floor, second floor, third floor etc. Conventional floor slabs are described here: https://www.designingbuildings.co.uk/wiki/Floor_slab#:˜:text=The%20item%20floo r%20slab%20usually.level%20or%20at%20upper%20levels.

It is appreciated that after the design phase including the method of FIGS. 2A-2B is completed, an installation phase typically takes place, which proceeds according to the design yielded by the design phase. Any suitable installation process may be employed, and methods herein need not be limiting in that respect. For example, the ledger may be pre-installed in a factory, or may be installed on-site e.g., as a construction area. Similarly, attachment of cassettes to one another may be in the field or in the factory, or both, depending e.g., on constraints which may limit transportation of post-assembled, or even partially assembled, cassettes. According to certain embodiments, all the building's floors, including all floor slabs, are designed in a design phase, and then each floor's panels or cassettes are installed as per the design, as well as connectors, ledger angles, etc. of FIGS. 33-36.

It is appreciated that cassette size determination is useful because, for example, if cassettes are too large they may not be transportable to the site, whereas if cassettes are too small, or if cassette fractions are permitted, this generates too much work and increases construction costs.

According to certain embodiments, one cassette dimension, its depth, is fixed, and does not change from building to building, whereas the cassette's length or width, or both, are determined per building, such that the floor plan is not matched to a prefixed size cassette: instead the floor plans determine which cassette dimensions are selected. Typically, dimensions are selected from among a discrete number of possible dimensions. According to certain embodiments, only one cassette type and/or size and/or design is employed for all buildings, however according to other embodiments, a relatively small plurality of cassette designs and/or types and/or sizes is employed for all buildings.

In some cases, the first direction tested by the tool to define a given rectangle as a field will be compatible e.g., will “pass” operation 1080 or 1090 or 1100 in FIG. 2B (in a system which has three rules represented respectively by operations 1080 or 1090 or 1100). In this case, a field may be defined, because the load of the cassettes which will cover that field, can be safely carried i.e., supported by the structural walls of the first direction.

In other cases, the first direction tested by the tool to define a field will not be compatible e.g., will “fail” operation 1080 or 1090 or 1100 in FIG. 2B. In this case the tool will try the second, perpendicular direction (e.g. FIGS. 2A-2B—operations 1110, 1140). In this case too, a field may be defined because the load of the cassettes which will cover that field, can be safely carried i.e., supported by the structural walls of the second, perpendicular direction.

Regarding the terms Current direction—used in operation 1080 in FIG. 2B, Defined direction-used in operation 1100 in FIG. 2B, and Default direction-used in operation 1110 in FIG. 2B (also operation 1130)—It is appreciated that typically, the default direction is along either of the dimensions of a current field, e.g. as predetermined by user input, and if the system fails to cover the floor safely when creating fields in the default direction, then the system attempts to cover the floor safely when creating fields in the orthogonal or perpendicular direction.

Current direction and “defined direction” may be used generally interchangeably. Both of these can be either the default direction (if that is what the system is currently using as a field-creating direction) or (if the default direction has already failed to yield a safe covering for the floor)—the current or defined direction is the perpendicular direction, because the perpendicular direction is what the system is currently using as a field-creating direction.

It is appreciated that, as shown, various operations in FIG. 2B are performed for an initial direction (e.g., a default direction) and then, if this direction fails to yield a safely supported tiling, the operations are performed again for the perpendicular direction i.e., a second time. Typically, one of the two directions always succeeds in yielding a safely supported tiling.

### Example

An example execution of the methods of FIGS. 2A-2B and 37 may be appreciated with reference to FIGS. 8-48. It is appreciated that tiling or populating fields initially comprises a digital operation (which may be undone e.g., if less than all of a field can be populated, the cassettes digitally placed in the field may be deleted). However, subsequently, e.g., once at least one field has been finally and successfully digitally tiled with floor cassettes, and more typically once all fields in at least one floor slab have been finally and successfully digitally tiled with floor cassettes, then the physical operation of physically populating the field/s occurs. The floor cassettes may be manufactured to order, depending on the desirable cassette sizes determined during the digital phase (which may proceed in accordance with any of the digital operations in FIGS. 2A and/or 2B and/or 37 and/or 54.

To appreciate execution of operations 1010, 1030 and 1050 in FIG. 2A according to an embodiment of the invention, consider FIGS. 8, 9 and 11 respectively.

Operation 1010 in FIG. 2A, inter alia, may use or be incorporated in architectural software applications such as Revit by Autodesk. For example. Revit may be used to generate a digital file which holds a building's design, using prefixed formulas to compute truss size, angle, etc., and the building's floor slab, for each of the building's levels, may be processed e.g., as per FIGS. 2A-2B herein to determine cassette sizing. The user may only set pre-defined limitations (e.g. length should not exceed value x. Size limitations may depend on manufacturing constraints (beam size, assembly line working area, etc.) or transportation limitations (max weight/size allowable for assembly line stations and/or for transporting by vehicle). In practice, these parameters may be left unchanged, as most of the limitations/constraints do not change from building to building. The spatial properties typically include preset recommendations that the user can either tweak (e.g. within certain system limits) or may use a prefixed recommended value. These recommendations may pertain to metadata regarding external dimensions of the cassettes or internal dimension limitations (e.g., minimal/maximal number of internal truss sections). The latter may impose certain limitations on top of the external ones. For example, a minimum number of sections may lead to a higher minimum size limit as each section on its own has some dimension limitations derived from its own structure.

As shown, with reference to FIG. 2A, and see e.g. FIG. 10, when operations 1030, 1040 are executed, (x,y) coordinates are typically saved for the walls' junction.

Refer to FIG. 13 to appreciate execution of FIG. 2B's operations 1080, 1090, 1100 in the example. Referring to FIG. 14, when operations 1110, 1140, 1080, 1090, 1100 are performed, vertical bounding walls (C, D) in the example are tested after the horizontal walls are found not to be appropriate. It is appreciated that in the example, walls C & D are structural within the defined distance range, and there are no cassettes between these two walls. Referring now to operation 1150 and FIG. 15, the field width is the distance between the structural walls, and the field length is equal to these walls' mutual length.

In the example, one execution of operations 1060, 1070 pertains as shown in FIG. 12 to a first relevant rectangle labelled as rectangle 15, whereas another execution of operations 1060, 1070 pertains, as shown in FIG. 17, to a subsequent or next relevant rectangle labelled as rectangle 25. After all fields have been processed (after the loop below operation 1060 has been executed for all fields), the flow of FIG. 2A terminates. Each “Logical rectangle” typically comprises a area confined, defined or bounded by 4 grid points which is typically evaluated e.g., if a given logical rectangle is known (e.g. from the building design) to cover an internal wall area, then that logical rectangle typically will not be transformed to a field since for this logical rectangle, there is no need for actual coverage by a cassette. All rectangles may be evaluated although shortcuts may be applied (e.g., evaluating such areas in advance, prior to using the grid.).

As shown in FIG. 18, when operations 1080, 1090, 1100 are executed, the horizontal bounding walls (A,B having been set as default) are structural, are within distance limits, and have no cassettes between them.

A distance limit may be defined as a maximum allowed distance between parallel (structural) walls, for example for initiating a search process (e.g., as shown in FIGS. 2A-2B and 37) based on maximum manufacturing dimensions of a single cassette and/or on any other geometrical limitation imposed by design.

Referring to FIG. 19, when operation 1150 is executed, the field width is the distance between the structural walls and the field's length is equal to these walls' mutual length. FIG. 20 pertains to execution of operation 1160 inter alia in the example.

It is appreciated that in FIG. 20, inter alia, thin horizontal lines vs. thin vertical lines may be used to indicate fields in which cassettes are supported by horizontal supporting walls vs. fields in which cassettes are supported by vertical supporting walls. More generally, each cassette and/or field typically has a direction which is determined by its trusses' layout, which may extend between horizontal supporting elements e.g., ledgers, or may alternatively extend between vertical supporting elements, e.g. ledgers.

FIG. 22 pertains to a single cassette field where the cassette is shorter than default to fit the field. Similarly, referring to FIG. 27 and to operations 1080, 1090, 1110, 1140, 1100, in the single cassette field, the cassette is again shorter than default to fit the field, thus, with reference to FIG. 28, when operations 1120, 1130 are executed, the last field is undone including deletion of the last field's cassettes. However, fortunately, the second possible direction for field creation has yet to be tested. Referring to FIG. 29 and to execution of operations 1080, 1090, 1100 in the example, it is appreciated that this second, perpendicular direction does allow a field to be created.

Still with reference to operation 1130, it is appreciated that if a field is created in a certain direction, say the horizontal direction, each new field created is typically horizontally adjacent to (has a vertical side in common with) a most recently created previous field, whereas if a field is created in the vertical direction, each new field is vertically adjacent to (has a horizontal side in common with) a most recently created previous field.

Generally, it is appreciated that creation of a field is not always possible. For example, a gap or distance between walls may be appropriate for cassette design if there are structural elements on both sides (right/left) of the gap, but not otherwise. For example, if a cassette can be supported by, on the right, a structural wall and, on the left, a structural beam, then field creation is possible.

With reference to FIGS. 30-31, it is appreciated that field 5 is now redefined. Specifically, in FIG. 30 the next field to be populated is identified, and in FIG. 31, the proper sized cassette has been assigned to this next field (field 5, in the example).

According to certain embodiments, there is no uniform cassette size used for an entire floor slab: instead, a uniform cassette size may be used to tile one field, but another uniform cassette size may be used to tile another field.

Referring now to FIG. 32, it is appreciated that when operation 1160 is performed, a cassette is created, The internal design of the cassette e.g. design of trusses and other supports therewithin may be determined at this time e.g. after the external dimensions of the cassette are known.

When operation 1150 is executed, then, as may be appreciated with reference to FIG. 38, the field width is the distance between structural walls and the field's length is equal to these wall's mutual length.

Referring now to FIG. 39, it is seen that a field with a certain length has been identified. FIG. 40 pertains to the execution, in the example of operation 1160 in FIG. 2B, as well as to execution of operations 2010, 2020, 2030 in the method of FIG. 37. The first cassette placement may be of a typical length.

In operation 1150, typically, a current logical rectangle is defined as a new field (e.g., as shown in FIG. 39). One dimension of the new field (which may arbitrarily be termed the field's “width”) equals the distance between structural elements supporting the logical elements and another dimension (which may arbitrarily be termed the field' “length”) may equal the length of the structural elements, if these face each other along their entire length, or may equal the “overlapping length” e.g. the length of the portions of the structural elements which face each other, thus “overlap”.

Regarding min/max length, as described in operations 2010, 2030 etc., it is appreciated that there may be constraints determining minimal and/or maximal cassette lengths which must be adhered to, e.g. due to the cassettes' manufacturing stages (size of machine may dictate upper and/or lower bounds for size of workpiece) and/or due to constraints on transportation of cassettes e.g. maximum weight for a cassette to be transported by a truck, or a maximal length imposed by either the truck or assembly line stations.

It is appreciated that the cassettes placed in operation 2030 of FIG. 37 may be equally spaced and/or equally sized.

The term “default” length and typical length e.g., in FIG. 40, or in FIG. 37, operation 2010, are used herein generally interchangeably, e.g., to refer to a predetermined initial cassette length that is used by default to populate fields, unless or until the method of FIGS. 2A-2B and 37 determine that the cassette length is to be increased or decreased.

Referring now to execution of the method of FIG. 37 (and with reference to FIG. 16 inter alia), FIGS. 41-42 pertain to execution of operations 2020, 2030 in the example, where FIG. 41 pertains to placement of a second cassette of typical length, and FIG. 24 pertains to a third cassette also of typical length. Referring now to FIG. 43 and to execution of operations 2050, 2030 in the example, it is seen that the remaining space is longer than the minimal cassette length. Referring to FIG. 44, when operations 2030, 2050 are executed, a shorter cassette is created. Referring now to FIG. 45, when operation 2050 is executed, cassettes having typical cassette length are placed. However, with reference to FIG. 46, when operations 2050, 2060 are performed, the remaining (not yet covered by cassettes) length of the field is found to be shorter than the defined minimal cassette length, and, as shown in FIG. 47, execution of operations 2050, 2060 again result in a remaining length which is shorter than the defined minimal cassette length. Subsequent execution of operations 2030, 2050, 2060 in the example may be appreciated with reference to FIG. 48.

It is appreciated that the embodiment of FIG. 37 is but one example of a method for populating a given field whose dimensions are given, in which the typical and preferred cassette length is the maximum allowed cassette length. Other examples can be deployed (emphasizing the fact that the field discovery process is the important one.

According to certain embodiments, the method generally populates the floor slab, using floor cassettes having one constant dimension e.g., length, typically a length (“typical” length which may be preset by the user for a given field population e.g., because this length is convenient from operational and/or installation perspectives) and a flexible second dimension, e.g., width e.g., depending on distances between structural elements beneath the floor cassette. It is appreciated, however, that the method also handles “leftovers”, regions in which the “typical” cassette length cannot be used.

In FIG. 37 specifically, the typical length is the maximum allowable length, given a set of constraints such as transportation constraints and/or machine constraints, however this is not intended to be limiting.

It is appreciated that in most cases there are indeed “leftovers”, since the dimensions of the field cannot precisely accommodate a preferred typical length. For example, given a field length of 8.2 meters and a typical cassette length of 2.5 meters, three cassettes of typical length can be fitted 3*2.5, however this yields a leftover of 0.7 meters. Regarding leftovers, in the fortunate case where the leftover is “big enough” (e.g., larger than a minimal length-say 0).4 meters—dictated by certain constraints e.g., the cassette manufacturing machines and/or minimal strength requirements), an additional cassette of the “leftover” or gap size may be manufactured. However, the leftover length may be smaller than the minimal length e.g., a 0.7 meter leftover, which is smaller than a minimal length limit of 1 meter. In this case, the method may remove one of the “typical sized” cassettes, yielding an enlarged leftover, which (being larger than the typical size) is by definition greater than the minimal size. The enlarged leftover may then be populated by two equally sized cassettes, each exceeding the minimal size. In some examples, e.g., if the minimum size is 1.75 meters, it may occur that the last stage (e.g., 2*1.6 of the previous example), cannot be used. In such cases, an additional “typical” cassette may be removed from the design. In the above example, this results in enlarging the leftover gap to 5.7 (as the field now includes only one single typical cassette, plus the gap). If two cassettes are used to cover this gap, they will be too large, however dividing the leftover gap into three yields, in the previous example, 5.7/3=1.9, which is greater than the minimum allowed, resulting in a final field population of 1 typical cassette+3 non-typical or “adjusted” cassettes (1×2.5+3×1.9).

Thus, according to certain embodiments, the method for populating a given field, during a design process, includes populating each field with typical-length cassettes, until the field either is complete, or is complete but for a leftover gap smaller than the typical length. In the latter case, an adjusted size cassette is inserted and/or if/as dictated by the minimal size, enough typical cassettes are removed to allow for adjusted sized cassettes, of larger-than-minimum and smaller-than maximum length, to cover the field.

According to certain embodiments, field length is populated by the smallest number of cassettes needed, given certain restrictions on minimal and/or maximal cassette size. For example, if max=3, min=2 and current field length is 7, then N=2 (number of equally sized cassettes) leads to 7/2=3.5 which is too large (3.5>max), whereas N=3 yields 7/3=2.33, which is acceptable (it is appreciated that N>3 yields cassette lengths which are below the minimum).

A particular feature of certain embodiments is that when populating fields with cassettes, one of the two possible directions (vertical or horizontal) is selected and population in that direction begins, using a given size of cassette, until one of two events occurs:
a. an entire field has been populated (“mission completed”-go on to next field or, if all fields in the floor slab have been populated, end) or
b. population of the current field fails e.g., because some cassettes have been populated into the field, however the remaining portion of the field is too large or too small to accept another cassette of the same size. Each time failure occurs, the method typically retreats, deleting the populated area which was filled by the failed attempt (e.g., deleting all cassettes which have been populated into the current field), and trying to populate the same field, either in the opposite direction and/or using a different cassette size.

According to certain embodiments, field population may try all possible sizes, from the minimal allowable size to the maximal allowable size, or vice versa, until the field is successfully populated.

The term “size” as used herein may refer to only one of the three cassette dimensions (say length), e.g. because width is fixed, since the distance between adjacent structural elements is known, and may even be fixed throughout a given building/project, and the third dimension, depth, is typically fixed for all projects and/or is beyond the scope of the present invention.

According to certain embodiments, field population may start populating each field using cassettes starting from the largest possible size, then decreasing size if/as needed.

It is appreciated that any suitable method may be used, to design deployment of structural elements e.g. in the floor slab beneath it.

According to certain embodiments, each field's length is measured, and an integer number of equally sized cassettes are used, whose common length falls between the minimal and maximal cassette length values. According to one example, the field length may be divided by the typical cassette length, then the method may round up or down to an integer value, then divide the field length by that integer value to obtain a final cassette length, to be used for all cassettes in that field. Thus, according to certain embodiments, minimization of the number of cassette-sizes is achieved by populating fields with equally sized cassettes to yield cassettes all the same size, for at least one field. Also, if several or many fields have the same length and width, cassettes for all of these fields may all be the same.

FIG. 54 aka Flow 3, is a method for field extraction and identification, and may be used to replace the field search operations of the method of FIGS. 2A-2B. The method of FIG. 54 typically includes, for Floor [N], an operation to retrieve digital file of plan of the floor below, hence Floor [N-1], and to retrieve all structural elements (e.g., walls, beams) and to create a table T by reviewing all construction elements and extracting element type (structural or not, wall or beam, etc.) therefrom, and corresponding rectangular cross section coordinates, and an operation to create a new table F which is a 2D sort representation of all points listed in table T (coordinates). Then, table F may be scanned (either by rows or by columns) to generate a list Lt of the smallest possible rectangles represented by 4-points. The method may classify the type of each rectangle (interior space, exterior space, in-wall, etc.) and, e.g., using the list of rectangles Lt, may create a new list Lu which contains the combined (unified) nearby rectangles of the same type, if the unified geometry forms a rectangle (of the same type). Eventually, Floor [n] Processing ends, and processing of each field may continue, e.g., as described herein, using list L as a source from which fields to be processed may be retrieved.

The method of FIG. 54 may include all or any subset of the following operations 3000-3080, suitably ordered e.g., as follows: in operation 3000, the process begins, for a floor slab N which may lie over a floor slab N-1 having structural elements whose locations are known. Typically, the method of FIG. 54 is performed for each floor e.g., from floor1 to floorN, however, if a current floor and the floor beneath it are identical to the previous floor and the floor below that, the cassette design and tiling arrangement may be copied, rather than performing the same computations once again.

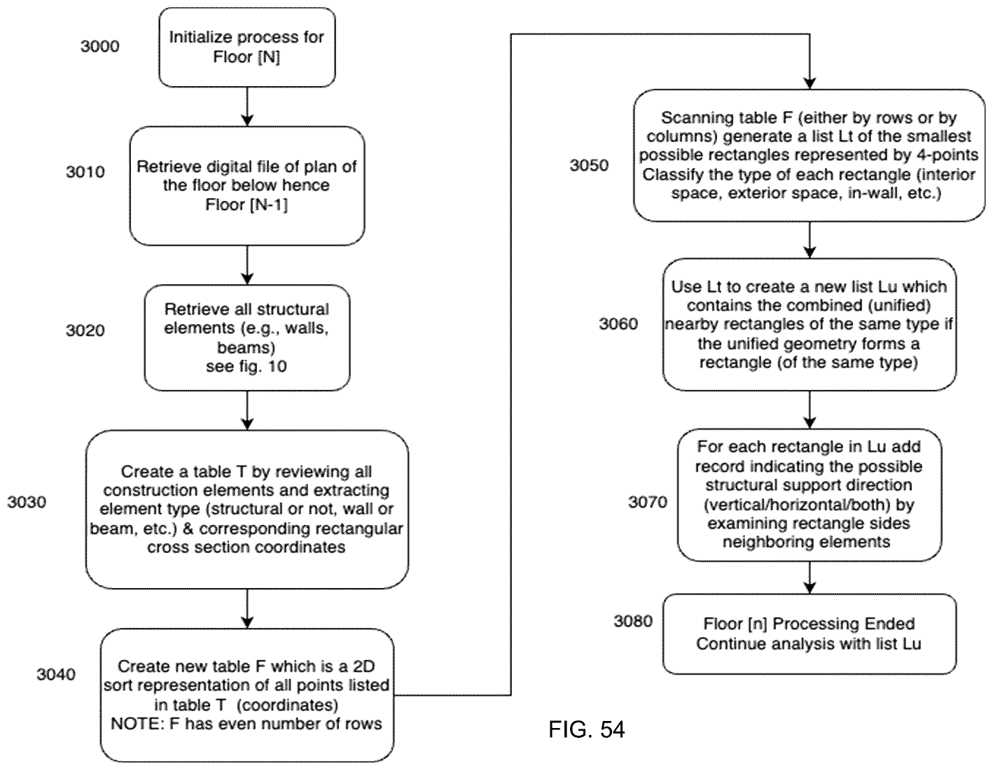

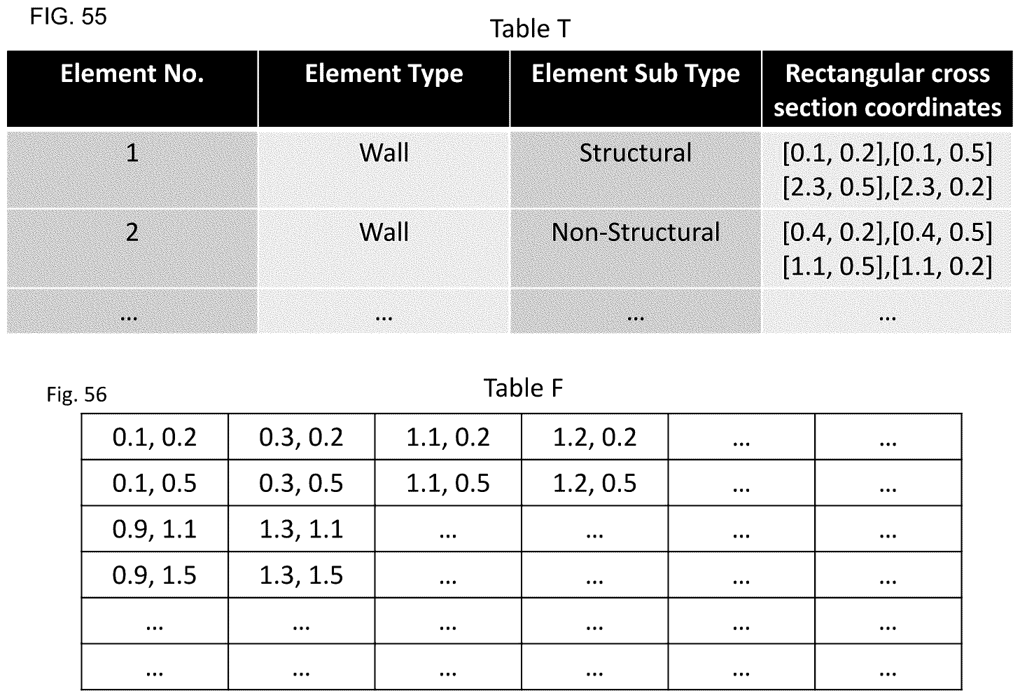

In operation 3010, this information regarding floor [N-1] may be retrieved from a digital file containing its design. In operation 3020, data identifying elements as structural or non-structural is identified, to determine whether these elements have or lack ability to carry the load of the cassettes. In operation 3030, 2D aspects of each element's cross section are extracted and may be used to form table T of FIG. 55. For example, each element can be described by at least one rectangle. “L shaped” or “T shaped” elements can be described by two or more rectangles and may contribute more than one rectangle each to the list. It is appreciated that construction elements such as walls may be either structural or non-structural.

In operation 3040, each rectangle is represented by four corner points in a two-dimensional plane. After all of the corner points of all rectangles are positioned in the 2D plane, the plane can be scanned row-step by row-step from “north” to “south” i.e. along a first axis and for each “row” from “west” to “east” i.e. along a second axis. The encountered points as scanned may be listed in the F matrix (“table F” of FIG. 56. Eventually F may resemble a matrix, yet, typically, less than all of its cells contain a coordinate, and therefore F is typically sparse. Typically, the matrix contains all grid points.

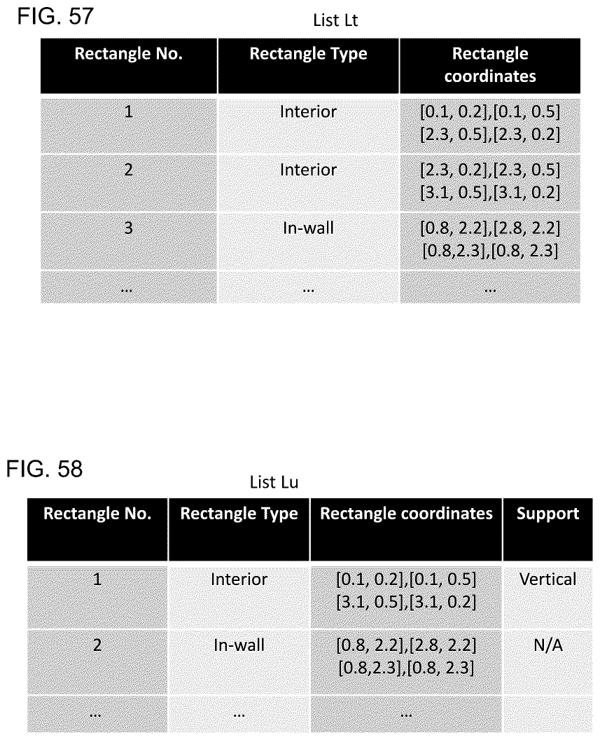

In operation 3050, four grid points are selected, representing a rectangle to be analyzed at later stages. The selection process employs the F matrix, scanning F row by row, and for each row moving through F's columns. An encountered point may be set, e.g., temporarily, as an anchor, and together with three adjacent points (1 horizontal, next point on the row, 2 vertical, using the next row) are tested for being a rectangle (the test may comprise determining whether sides are vertical and horizontal). A valid point-quadrupole may then, e.g., responsively, be added to memory e.g., to the Lt list of FIG. 57. The method may classify the rectangles into various types.

Operation 3060 may be used to consolidate, or merge, or unite, or combine adjacent rectangles into a new list Lu e.g., as shown in FIG. 58 which represents a larger area of the same type and constitutes a new and larger rectangle. Example 1: the first 2 rows in the Lt table of FIG. 57 describe two adjacent touching rectangles which are then unified/merged into a single rectangle, as described by the first row of new list Lu e.g. as shown in FIG. 58. The number of rectangles is thus reduced as the combined new rectangles are larger. In general, if 2 rectangles of the same type are candidates to be merged, of which one rectangle is represented by its corner points as:

{[a,b],[a,b+y],[a+x,b+y],[a+x,b]},
and the other rectangle is {[a,b], [a,b+y], [a+x+z,b+y], [a+x+z,b]},
then the new rectangle may be {[a,b], [a,b+y], [a+x+z,b+y], [a+x+z,b]}.

Example 2: field 1 in FIG. 15 includes plural rectangles (also termed herein “logical rectangles”) which are generated by the grid creation process described herein e.g., as shown in FIGS. 12-14. Initially, the Lt list of FIG. 57 may include these three rectangles, and then by unification these rectangles may be combined or merged into a single rectangle or field: these combined rectangles or fields may be stored in memory e.g., listed in Lu. Then, for methods like FIG. 37 which are performed per each field, the fields may be retrieved easily from memory, e.g., from list Lu. It is appreciated that Lu is a smaller or shorter list than Lt, as some of the rectangular shapes in Lt have been combined. According to certain embodiments, the Lu list of FIG. 58 contains unified rectangles of various types, yet during field population, the method may use only those rectangles that are designated to be populated with cassettes (e.g., interior space rectangles may be used, and rectangles which cover walls rather than interior space, may not be used).

According to certain embodiments, the loop beginning with operation 1060, in the method of FIG. 2A, may be performed for each rectangle in the list of unified rectangles Lu generated by operation 3060 in FIG. 54.

In operation 3070, for each rectangle in the Lu list of FIG. 58, metadata may be added by using the parallel side positions of the rectangle, to determine whether these sides rest on supportive structures. For an internal area to be covered by cassettes, the directions, as determined by supported sides orientation, may be indicated as either “vertical”, “horizontal”, “both”, “neither” or “non-applicable”.

The Lu list of FIG. 58 is then available for further processing by other flows herein. For example, the Lu list may be used as input (source from which fields may be retrieved) for the method of FIG. 37.

As apparent from FIG. 54, each field may comprise the largest possible rectangle that can be formed by combining smaller rectangles of a single type.

It is appreciated that the method typically does not combine/unify rectangles which are not of the same type. For example, given two identical rectangles within a grid which may be generated as described herein, which share one side, including a first rectangle which is an interior portion of a wall, and a second rectangle which is a portion of a room interior. Although they are adjacent, these are typically undesirable to combine, as they are not of the same type. In contrast, if both rectangles are within the same interior room space, they are typically combined.

Any suitable method may be employed to determine to which wall or room interior given rectangles belong to, e.g. by comparison of a grid to a known design of the building.

It is appreciated that, in certain cases, the interior room rectangle should have been chosen in advance to be the largest possible size, but due to the grid formation process, certain grid points partition the room space into smaller rectangles which the unification process unites, to recover the largest spaces possible. It is appreciated that the grid formation process may disregard the issue of which rectangles are within a wall, and which are within an open space.

According to certain embodiments, any array of rectangles may be combined into a single larger rectangle e.g. if all rectangles in the array are of the same type e.g., belong to a single room, or a single wall. Example: given a room size of 4×4 meters which, due to walls locations and other beam locations, has yielded a grid in which the room is divided into four equally sized rectangles 4×1, sharing sides, adjacent on to each other. The unification process may be used to combine all four into a single 4×4 rectangle.

According to certain embodiments, the following design method may be used (all or any subset of the operations thereof, in any suitable order e.g. as below) and may be combined with all or any subset of the specific operations of FIGS. 2A-2B and FIG. 37:
Operation d10. design or deploy structural elements designed to support a floor slab to be built above them
Operation d20. Define fields, to be populated by floor cassettes, which extend between pairs of parallel structural elements or pairs of parallel structural element portions. Select one of the fields as the current field
Operation d30. Select, as an initial value for current cassette size, an initial cassette size including a first dimension whose length corresponds to one of the dimensions of the field, and a second dimension whose length falls within an allowable range e.g. is smaller than a maximal cassette size limit, and/or is larger than a minimal cassette size limit
Operation d40. Populate a current field, laying down cassettes one next to another, such that each cassette's first dimension extends along the field dimension of corresponding length, using cassettes of the current cassette size: if population fails before the field is fully populated, delete all cassettes populated thus far, systematically increment or decrement the second dimension and repopulate, again unless and until population fails.
Operation d50. If population of the current field eventually succeeds, continue to a next field from among the fields defined in operation 20 and repeat operation 40, using a suitable current size e.g., the initial cassette size selected in operation 30 or the size eventually used when the previous field was successfully populated. Repeat until all fields defined in operation 20 are successfully populated, then end.
Operation d60. If population of a current field always fails, for all second cassette dimensions within the allowable range, repeat operations 30 and 40, but use cassettes whose first dimension corresponds to the other field dimension, such that, this time, a different field dimension serves as the “field dimension of corresponding length”.

The system herein is useful for HVAC/MEP professionals, installers, homeowners, construction professionals, interior designers, architects, sustainability engineers, MEP engineers, inter alia. Another advantage of certain embodiments is that MEP (Mechanical, Electrical, and Plumbing) and HVAC (Heating, Ventilation, and Air Conditioning) onsite (construction area) work are obviated, because the cassette may contain these systems which need not be installed on the site. The internal (panel) MEP/HVAC work is done en masse at the cassette/panels fabrication plant.

Another advantage of certain embodiments is accommodation for the fact that the highly sophisticated digital manufacturing process by which structural floor elements (e.g. floor cassettes) are produced, is, by virtue of systems and methods and computer program products herewithin, rendered compatible and optimized vis a vis a chaotic physical reality, in which each building stands on a lot with its own unique physical configuration, often subject to municipal restrictions, which vary greatly between city to city, and to personal design preferences of owners or architects, such that the sizes of rooms and living spaces are almost infinitely disparate. It is appreciated that walls of these rooms play an important role as structural elements. Thus, in practice, the complex reality is that floor cassettes are supported by structural elements in the floor beneath it, which are typically positioned and designed according to a host of considerations, and are in no way designed to ease efficient manufacture of floor cassettes to be transported and deployed atop these structural elements.

It is appreciated that terminology such as “mandatory”, “required”, “need” and “must” refer to implementation choices made within the context of a particular implementation or application described herewithin for clarity, and are not intended to be limiting, since, in an alternative implementation, the same elements might be defined as not mandatory and not required, or might even be eliminated altogether.

Components described herein as software may, alternatively, be implemented wholly or partly in hardware and/or firmware, if desired, using conventional techniques, and vice-versa. Each module or component or processor may be centralized in a single physical location or physical device or distributed over several physical locations or physical devices.

Included in the scope of the present disclosure, inter alia, are electromagnetic signals in accordance with the description herein. These may carry computer-readable instructions for performing any or all of the operations of any of the methods shown and described herein, in any suitable order including simultaneous performance of suitable groups of operations, as appropriate. Included in the scope of the present disclosure, inter alia, are machine-readable instructions for performing any or all of the operations of any of the methods shown and described herein, in any suitable order; program storage devices readable by machine, tangibly embodying a program of instructions executable by the machine to perform any or all of the operations of any of the methods shown and described herein, in any suitable order i.e. not necessarily as shown, including performing various operations in parallel or concurrently, rather than sequentially as shown: a computer program product comprising a computer useable medium having computer readable program code, such as executable code, having embodied therein, and/or including computer readable program code, for performing any or all of the operations of any of the methods shown and described herein, in any suitable order: any technical effects brought about by any or all of the operations of any of the methods shown and described herein, when performed in any suitable order; any suitable apparatus or device or combination of such, programmed to perform, alone or in combination, any or all of the operations of any of the methods shown and described herein, in any suitable order: electronic devices, each including at least one processor and/or cooperating input device and/or output device and operative to perform, e.g. in software, any operations shown and described herein: information storage devices or physical records, such as disks or hard drives, causing at least one computer or other device to be configured so as to carry out any or all of the operations of any of the methods shown and described herein, in any suitable order: at least one program pre-stored e.g. in memory or on an information network such as the Internet, before or after being downloaded, which embodies any or all of the operations of any of the methods shown and described herein, in any suitable order, and the method of uploading or downloading such, and a system including server/s and/or client/s for using such: at least one processor configured to perform any combination of the described operations or to execute any combination of the described modules; and hardware which performs any or all of the operations of any of the methods shown and described herein, in any suitable order, either alone or in conjunction with software. Any computer-readable or machine-readable media described herein is intended to include non-transitory computer- or machine-readable media.

Any computations or other forms of analysis described herein may be performed by a suitable computerized method. Any operation or functionality described herein may be wholly or partially computer-implemented e.g., by one or more processors. The invention shown and described herein may include (a) using a computerized method to identify a solution to any of the problems or for any of the objectives described herein, the solution optionally including at least one of a decision, an action, a product, a service, or any other information described herein that impacts, in a positive manner, a problem or objectives described herein; and (b) outputting the solution.

The system may, if desired, be implemented as a network—e.g. web-based system employing software, computers, routers and telecommunications equipment, as appropriate.

Any suitable deployment may be employed to provide functionalities e.g., software functionalities shown and described herein. For example, a server may store certain applications, for download to clients, which are executed at the client side, the server side serving only as a storehouse. Any or all functionalities e.g., software functionalities shown and described herein, may be deployed in a cloud environment. Clients e.g., mobile communication devices, such as smartphones, may be operatively associated with, but external to the cloud.

The scope of the present invention is not limited to structures and functions specifically described herein, and is also intended to include devices which have the capacity to yield a structure, or perform a function, described herein, such that even though users of the device may not use the capacity, they are, if they so desire, able to modify the device to obtain the structure or function.

Any “if-then” logic described herein is intended to include embodiments in which a processor is programmed to repeatedly determine whether condition x, which is sometimes true and sometimes false, is currently true or false and to perform y each time x is determined to be true, thereby to yield a processor which performs y at least once, typically on an “if and only if” basis, e.g. triggered only by determinations that x is true, and never by determinations that x is false.

Any determination of a state or condition described herein, and/or other data generated herein, may be harnessed for any suitable technical effect. For example, the determination may be transmitted or fed to any suitable hardware, firmware or software module, which is known or which is described herein to have capabilities to perform a technical operation responsive to the state or condition. The technical operation may for example comprise changing the state or condition or may more generally cause any outcome which is technically advantageous, given the state or condition or data, and/or may prevent at least one outcome which is disadvantageous given the state or condition or data. Alternatively or in addition, an alert may be provided to an appropriate human operator, or to an appropriate external system.

Features of the present invention, including operations, which are described in the context of separate embodiments may also be provided in combination in a single embodiment. For example, a system embodiment is intended to include a corresponding process embodiment, and vice versa. Also, each system embodiment is intended to include a server-centered “view” or client centered “view”, or “view” from any other node of the system, of the entire functionality of the system, computer-readable medium, apparatus, including only those functionalities performed at that server or client or node. Features may also be combined with features known in the art, and particularly, although not limited to, those described in the Background section, or in publications mentioned therein.

Conversely, features of the invention, including operations, which are described for brevity in the context of a single embodiment or in a certain order, may be provided separately, or in any suitable sub-combination, including with features known in the art (particularly although not limited to those described in the Background section or in publications mentioned therein) or in a different order. “e.g.” is used herein in the sense of a specific example which is not intended to be limiting. Each method may comprise all or any subset of the operations illustrated or described, suitably ordered e.g., as illustrated or described herein.

Devices, apparatus or systems shown coupled in any of the drawings may in fact be integrated into a single platform in certain embodiments, or may be coupled via any appropriate wired or wireless coupling, such as but not limited to optical fiber, Ethernet, Wireless LAN, HomePNA, power line communication, cell phone, Smart Phone (e.g., iPhone), Tablet, Laptop, PDA, Blackberry GPRS, Satellite including GPS, or other mobile delivery. It is appreciated that in the description and drawings shown and described herein, functionalities described or illustrated as systems and sub-units thereof can also be provided as methods and operations therewithin, and functionalities described or illustrated as methods and operations therewithin can also be provided as systems and sub-units thereof. The scale used to illustrate various elements in the drawings is merely exemplary and/or appropriate for clarity of presentation, and is not intended to be limiting.

Any suitable communication may be employed between separate units herein e.g. wired data communication and/or in short-range radio communication with sensors such as cameras e.g. via Wifi, Bluetooth or Zigbee.

It is appreciated that implementation via a cellular app as described herein is but an example, and, instead, embodiments of the present invention may be implemented, say, as a smartphone SDK, as a hardware component, as an STK application, or as suitable combinations of any of the above.

Any processing functionality illustrated (or described herein) may be executed by any device having a processor, such as but not limited to a mobile telephone, set-top-box, TV, remote desktop computer, game console, tablet, mobile e.g. laptop or other computer terminal, embedded remote unit, which may either be networked itself (may itself be a node in a conventional communication network e.g.) or may be conventionally tethered to a networked device (to a device which is a node in a conventional communication network, or is tethered directly or indirectly/ultimately to such a node).

Any operation or characteristic described herein may be performed by another actor outside the scope of the patent application and the description is intended to include apparatus, whether hardware, firmware, or software, which is configured to perform, enable, or facilitate that operation or to enable, facilitate, or provide that characteristic.

The terms processor or controller or module or logic as used herein are intended to include hardware such as computer microprocessors or hardware processors, which typically have digital memory and processing capacity, such as those available from, say Intel and Advanced Micro Devices (AMD). Any operation or functionality or computation or logic described herein may be implemented entirely or in any part on any suitable circuitry, including any such computer microprocessor/s, as well as in firmware or in hardware, or any combination thereof.

It is appreciated that elements illustrated in more than one drawings, and/or elements in the written description may still be combined into a single embodiment, except if otherwise specifically clarified herewithin. Any of the systems shown and described herein may be used to implement or may be combined with, any of the operations or methods shown and described herein.

It is appreciated that any features, properties, logic, modules, blocks, operations or functionalities described herein, which are, for clarity, described in the context of separate embodiments, may also be provided in combination in a single embodiment, except where the specification or general knowledge specifically indicates that certain teachings are mutually contradictory, and cannot be combined. Any of the systems shown and described herein may be used to implement, or may be combined with, any of the operations or methods shown and described herein.

Conversely, any modules, blocks, operations or functionalities described herein, which are, for brevity, described in the context of a single embodiment, may also be provided separately or in any suitable sub-combination, including with features known in the art. Each element e.g., operation described herein, may have all characteristics and attributes described or illustrated herein, or, according to other embodiments, may have any subset of the characteristics or attributes described herein.

The invention includes but is not limited to the embodiments recited in the claims.

1. A system for designing structural floors, the system comprising:
a hardware processor configured to perform an iteration including:
determining whether an individual rectangle, defined within a building area, can or cannot, when covered by whole floor cassettes, be safely carried by either the vertical structural supporting elements beneath that rectangle or by the horizontal structural supporting elements beneath said individual rectangle, including:
digitally covering said individual rectangle with whole digital cassettes, for at least one individual rectangle which, when covered by whole cassettes, can be safely carried by either the vertical structural supporting elements beneath that rectangle or by the horizontal structural supporting elements beneath that individual rectangle; and
digitally deleting cassettes which digitally cover at least one rectangle which precede/s said individual rectangle, for at least one individual rectangle which, when covered by whole cassettes, cannot be safely carried by the vertical structural supporting elements beneath that rectangle and cannot be safely carried by the horizontal structural supporting elements beneath that individual rectangle;
and wherein said hardware processor is used to repeat said iteration for each individual rectangle, from among all rectangles defined within the building area, which is not digitally covered with cassettes, thereby to design a structural floor.

2. The system of claim 1, wherein said deleting includes deleting cassettes covering but one rectangle which precedes said individual rectangle, and deleting another rectangle which precedes said individual rectangle only during a subsequent iteration for at least one rectangle R which, after said but one rectangle is deleted, is not covered with cassettes, and only if said rectangle R when covered by whole cassettes, cannot be safely carried by the vertical structural supporting elements beneath rectangle R and cannot be safely carried by the horizontal structural supporting elements beneath rectangle R.

3. The system of claim 1, wherein said iterations are repeated, proceeding over rectangles defined not covered with cassettes within a building area, in a predetermined order.

4. The system of claim 1, wherein system rules which take in account known structural characteristics of physical cassettes, are stored in memory and are applied to determine whether an individual rectangle, defined within a building area, can or cannot, when covered by whole physical cassettes corresponding in size to said digital cassettes, be safely carried by either the vertical structural supporting elements beneath that rectangle, or by the horizontal structural supporting elements beneath said individual rectangle.

5. A method for designing structural floors, the method comprising:
using a hardware processor to perform an iteration including:
determining whether an individual rectangle, defined within a building area, can or cannot, when covered by whole cassettes, be safely carried by either the vertical structural supporting elements beneath that rectangle, or by the horizontal structural supporting elements beneath said individual rectangle, including:
digitally covering said individual rectangle with whole digital cassettes, if the individual rectangle, when covered by whole physical cassettes corresponding in size to said digital cassettes, can be safely carried by either the vertical structural supporting elements beneath that rectangle, or by the horizontal structural supporting elements beneath that individual rectangle; and
digitally deleting digital cassettes which digitally cover at least one rectangle which precede/s said individual rectangle, if the individual rectangle, when covered by whole physical cassettes, corresponding in size to said digital cassettes, cannot be safely carried by the vertical structural supporting elements beneath that rectangle, and cannot be safely carried by the horizontal structural supporting elements beneath that individual rectangle; and
using said hardware processor to repeat said iteration for each individual rectangle, from among all rectangles defined within the building area, which is not digitally covered with digital cassettes, thereby to design a structural floor.

6. The method of claim 5, and also comprising providing N physical cassettes of a given size, once all rectangles defined within the building area have been digitally covered, by the hardware processor, with N whole cassettes of said given size.

7. The method of claim 6, and also comprising building the structural floor by physically covering each of said rectangles with physical cassettes, wherein the physical cassettes correspond in size to the digital cassettes.

8. The system of claim 1, wherein each time a current iteration is performed subsequent to cassettes having been deleted in a previous iteration, whole digital cassettes used to digitally cover at least one rectangle during said current iteration, are smaller than the cassettes deleted during said previous iteration.

9. The system of claim 8, wherein all digital cassettes used for digitally covering are longer than a minimum allowed cassette length stored in the system.

10. The method of claim 7, wherein system rules which take in account known structural characteristics of physical cassettes, are stored in memory and are applied to determine whether an individual rectangle, defined within a building area, can or cannot, when covered by whole physical cassettes corresponding in size to said digital cassettes, be safely carried by either the vertical structural supporting elements beneath that rectangle or by the horizontal structural supporting elements beneath said individual rectangle.

11. The method of claim 10, and wherein said physical cassettes used to physically cover rectangles when building the structural floor, have said known structural characteristics.

12. A computer program product, comprising a non-transitory tangible computer readable medium having computer readable program code embodied therein, said computer readable program code adapted to be executed to implement a method for designing structural floors, the method comprising:
using a hardware processor to perform an iteration including:
determining whether an individual rectangle, defined within a building area, can or cannot, when covered by whole cassettes, be safely carried by either the vertical structural supporting elements beneath that rectangle or by the horizontal structural supporting elements beneath said individual rectangle, including:
digitally covering said individual rectangle with whole digital cassettes, if the individual rectangle, when covered by whole physical cassettes corresponding in size to said digital cassettes, can be safely carried by either the vertical structural supporting elements beneath that rectangle or by the horizontal structural supporting elements beneath that individual rectangle; and
digitally deleting digital cassettes which digitally cover at least one rectangle which precede/s said individual rectangle, if the individual rectangle, when covered by whole physical cassettes, corresponding in size to said digital cassettes, cannot be safely carried by the vertical structural supporting elements beneath that rectangle and cannot be safely carried by the horizontal structural supporting elements beneath that individual rectangle; and
using said hardware processor to repeat said iteration for each individual rectangle, from among all rectangles defined within the building area, which is not digitally covered with digital cassettes, thereby to design a structural floor.

13. The system of claim 1, wherein said hardware processor repeats said iteration until said rectangle is digitally covered with cassettes which can be safely carried by either the vertical structural walls beneath that rectangle, or by the horizontal structural walls beneath said individual rectangle.

14. The system of claim 1, wherein said structural supporting elements comprise structural supporting walls, beams, or ledgers.

15. The system of claim 1, wherein when at least one iteration fails for a first size of cassettes, because the rectangle cannot be safely carried by at least one of the vertical structural supporting elements beneath that rectangle or the horizontal structural supporting elements beneath that rectangle, and wherein another iteration is then performed for a second size of cassettes.

16. The system of claim 15, wherein one dimension, D1, of the second size of cassettes, is smaller than dimension D1 of the first size of cassettes.

17. The system of claim 16, wherein said another iteration comprises a sequence of plural iterations, performed using a respective sequence of cassettes having a respective sequence of cassette sizes having one dimension, D1, whose size is s2, s3, s4 respectively, and wherein s4 is smaller than s3 which is smaller than s2, thereby to prefer a flooring plan which uses larger cassettes over a flooring plan which uses smaller cassettes.

18. The system of claim 1, wherein a dimension D2 of the cassettes is equal to a distance between supporting elements beneath that cassette.

19. The system of claim 17, wherein the cassettes in the sequence of cassettes all have a dimension D2 equal to a distance between supporting elements beneath cassettes.

20. The system of claim 1, wherein said determining comprises, for at least one floor F, retrieving all structural elements from a digital plan of a floor below floor F including each element's type (interior space, exterior space, in-wall, etc.) and coordinates, creating, therefrom, a 2D sort representation of all said structural elements; and, accordingly, generating a list of rectangles including merging plural adjacent rectangles of a single type into a single rectangle.

21. The system of claim 20, wherein a floor area corresponding to the single rectangle is physically populated by floor cassettes and at least two parallel sides of the single rectangle are physically supported by structural elements in a floor slab below.

22. The system of claim 1, wherein said digitally covering said individual rectangle with whole digital cassettes comprises identifying, in a grid of lines, logical rectangles which enclose interior spaces, defining said logical rectangles as fields and digitally covering said fields with whole digital cassettes.

23. The system of claim 22, wherein said defining said logical rectangles as fields comprises unifying plural logical rectangles, found to cover portions of an interior space whose location and dimensions are known from a building design file, into a single larger logical rectangle covering said interior space which includes all of said portions.
